(19) United States
(12) Patent Application Publication
(10) Pub. No.: US 2011/0186798 A1
(43) Pub. Date: Aug. 4, 2011

(54) Phase Changeable Memory Devices and Methods of Forming the Same

(76) Inventors: Hyun-Suk Kwon, Seoul (KR); Hyeyoung Park, Seongnam-si (KR); Jeonghee Park, Hwaseong-si (KR); Gyuhwan Oh, Hwaseong-si (KR); Jinho Oh, Seongnam-si (KR); Doo-Hwan Park, Yongin-si (KR)

(21) Appl. No.: 13/019,822

(22) Filed: Feb. 2, 2011

(30) Foreign Application Priority Data
Feb. 4, 2010 (KR) 10-2010-0010454

(51) Int. Cl. H01L 45/00

(52) U.S. Cl. 257/2; 257/E45.002

(57) ABSTRACT

Phase changeable memory devices are provided including a mold insulating layer on a substrate, the mold insulating layer defining an opening therein. A phase-change material layer is provided in the opening. The phase-change material includes an upper surface that is below a surface of the mold insulating layer. A first electrode is provided in the opening and on the phase-change material layer. A spacer is provided between a sidewall of the mold insulating layer and the phase-change material layer and the first electrode. The upper surface of the first electrode is coplanar with the surface of the mold insulating layer. Related methods are also provided.

### CLAIM OF PRIORITY

This application claims priority to Korean Patent Application 10-2010-0010454, filed Feb. 4, 2010, the contents of which are hereby incorporated herein by reference.

### FIELD

This invention relates to semiconductor memory devices and methods of forming the same and, more particularly, to phase changeable memory devices and methods of forming the same.

### BACKGROUND

Semiconductor memory devices are broadly classified into volatile memory devices and non-volatile memory devices. The volatile memory devices lose stored data when power is cut off, whereas the non-volatile memory devices are capable of maintaining stored data even when power is cut off.

Generally, the non-volatile memory device is a device capable of erasing and programming data and capable of storing data even when power is removed from the device. Accordingly, the non-volatile memory device has recently been used in various fields.

As the non-volatile memory device, there have been developed variable-resistance memory devices such as a Resistive Random Access Memory (ReRAM) and a phase-change random access memory. The resistance value of materials forming the variable resistance semiconductor memory devices are varied in accordance with current or voltage. Even when supply of current or voltage is removed, the variable resistance semiconductor memory devices are capable of maintaining the resistance value. In particular, the phase-change random access memory uses a phase-change material capable of electrically changing different structured states indicating different reading characteristics. The phase-change random access memory device (PRAM) has a fast operation speed and a highly integrated structure.

### SUMMARY

Some embodiments of the present inventive concept provide phase changeable memory devices including a mold insulating layer on a substrate, the mold insulating layer defining an opening therein. A phase-change material layer is provided in the opening. The phase-change material includes an upper surface that is below a surface of the mold insulating layer. A first electrode is provided in the opening and on the phase-change material layer. A spacer is provided between a sidewall of the mold insulating layer and the phase-change material layer and the first electrode. The upper surface of the first electrode is coplanar with the surface of the mold insulating layer.

In further embodiments, the substrate may include a second electrode electrically connected to a lower surface of the phase-change material layer.

In still further embodiments, the opening may be completely filled with the phase-change material layer and the first electrode.

In some embodiments, the phase-change material layer may include a bottom portion that contacts the second electrode and a sidewall portion extending from the bottom portion to the first electrode. The phase-change material layer may have a U-shaped cross-section including the bottom portion and the sidewall portion. The first electrode may be locally formed on an upper surface of the sidewall portion of the phase-change material layer.

In further embodiments, a gap-fill insulating layer may be provided filling an inner space formed by the phase-change material layer and the first electrode. A protective layer may be provided between the gap-fill insulating layer, and the phase-change material layer and the first electrode.

In still further embodiments, the phase-change material layer may have an L-shaped cross-section including the bottom portion and the sidewall portion.

Some embodiments of the present inventive concept provide methods of forming a phase changeable memory device including forming a mold insulating layer that defines an opening on a substrate; forming a spacer on a sidewall of the mold insulating layer; forming a phase-change material layer with an upper surface below a surface of the mold insulating layer in the opening in which the spacer is formed; and forming a first electrode on the phase-change material layer in the opening, wherein an upper surface of the first electrode is coplanar with the surface of the mold insulating layer.

In further embodiments, forming of the phase-change material layer may include forming a phase-change material film to cover the surface of the mold insulating layer, while filling the opening; forming the phase-change material layer filling the opening by performing a planarization to the phase-change material film; and lowering an upper surface of the phase-change material layer below the surface of the mold insulating film through a selective etching process.

In still further embodiments, the selective etching process may be a reactive ion etching process using RF power.

In some embodiments, the first electrode may be formed on the phase-change material layer so as to fill the opening.

In further embodiments, forming of the phase-change material layer may include forming a phase-change material film along a profile of the mold insulating layer including the opening; forming a gap-fill insulating layer filling the opening on a region where the phase-change insulating film is formed; forming a gap-fill insulating layer pattern and the phase-change material layer filling the opening by performing a planarization process to the gap-fill insulating layer and the phase-change material film; and lowering an upper surface of the phase-change material layer below a surface of the mold insulating film by a selective etching process.

In still further embodiments, the method may further include forming a protective layer on the phase-change material film, before forming the gap-fill insulating layer.

In some embodiments, the selective etching process may be a reactive ion etching process using RF power.

In further embodiments, the first electrode may be locally formed on the upper surface of the phase-change material layer.

In still further embodiments, forming of the phase-change material layer may include forming a phase-change material film along a profile of the mold insulating layer including the opening; conformally forming a protective layer on the phase-change material film; forming one pair of protective layer spacers distant from each other in the opening by performing an anisotropic etching process to the protective layer; forming one pair of phase-change material layers distant from each other by etching the phase-change material film using the one pair of protective layer spacers as etching masks; forming a gap-fill insulating layer filling the opening on the one pair of protective layer spacers distant from each other and the regions where the one pair of phase-change material layers are formed; and lowering upper surfaces of the one pair of phase-change material layers below the surface of the mold insulating layer through a selective etching process.

In some embodiments, the selective etching process may be a reactive ion etching process using RF power.

In further embodiments, the first electrode may be locally formed on the upper surfaces of the one pair of phase-change material layers.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept.

FIG. 1 is a circuit diagram illustrating a memory cell array of a phase changeable memory device according to some embodiments of the inventive concept.

FIG. 2 is a diagram illustrating the overall layout of a phase changeable memory device according to some embodiments of the inventive concept.

FIG. 3 is a cross-section illustrating the phase changeable memory device taken along the line I-I′ of FIG. 2 according to some embodiments of the inventive concept.

FIG. 4 is a diagram illustrating the overall layout of a phase changeable memory device according to some embodiments of the inventive concept.

FIG. 5 is a cross-section illustrating the phase changeable memory device taken along the line I-I′ of FIG. 4 according to some embodiments of the inventive concept.

FIG. 6 is a diagram illustrating the overall layout of a phase changeable memory device according to some embodiments of the inventive concept.

FIG. 7 is a cross-section illustrating the phase changeable memory device taken along the line I-I′ of FIG. 6 according to some embodiments of the inventive concept.

FIG. 8 is a diagram illustrating the overall layout of a phase changeable memory device according to some embodiments of the inventive concept.

FIG. 9 is a cross-section illustrating the phase changeable memory device taken along the line I-I′ of FIG. 8 according to some embodiments of the inventive concept.

FIG. 10 is a diagram illustrating the overall layout of a phase changeable memory device according to some embodiments of the inventive concept.

FIG. 11 is a cross-section illustrating the phase changeable memory device taken along the line I-I′ of FIG. 10 according to some embodiments of the inventive concept.

FIGS. 12A through 15B are diagrams illustrating examples of a lower electrode of the phase changeable memory device according to some embodiments of the inventive concept.

FIGS. 16 to 25 are cross-sections taken along the line I-I′ of FIG. 2 illustrating processing steps in the fabrication of phase changeable memory device according to some embodiments of the inventive concept.

FIGS. 26 to 34 are cross-sections taken along the line I-I′ of FIG. 4 illustrating processing steps in the fabrication of phase changeable memory device according to some embodiments of the inventive concept.

FIGS. 35 to 40 are cross-sections taken along the line I-I′ of FIG. 6 illustrating processing steps in the fabrication of phase changeable memory device according to some embodiments of the inventive concept.

FIG. 41 is a schematic block diagram illustrating an example of a memory system including the phase changeable memory device according to some embodiments of the inventive concept.

FIG. 42 is a schematic block diagram illustrating an example of a memory card including the phase changeable memory device according to some embodiments of the inventive concept.

FIG. 43 is a schematic block diagram illustrating an example of an information processing system on which a non-volatile memory device according to some embodiments of the inventive concept.

### DETAILED DESCRIPTION OF EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third and the like. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates, otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

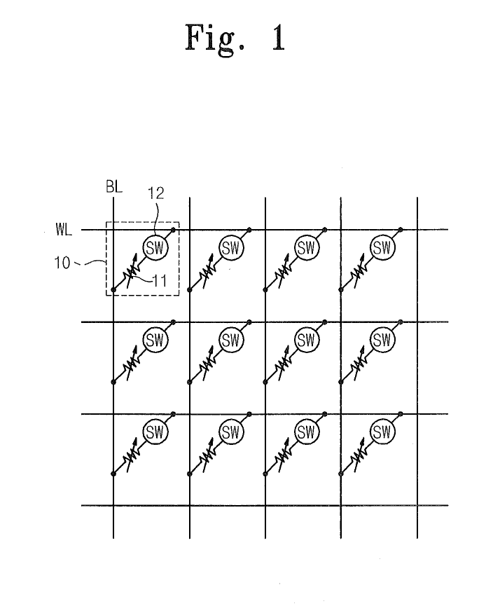

Referring first to FIG. 1, a circuit diagram illustrating a memory cell array of a phase changeable memory device according to some embodiments of the inventive concept will be discussed. As illustrated in FIG. 1, a plurality of memory cells 10 may be arranged in a matrix form. The memory cells 10 may each include a phase changeable element 11 and a selective element 12. The phase changeable element 11 and the selective element 12 may be interposed between a bit line BL and a word line WL.

The phase state of the phase changeable element 11 may be determined depending on the amount of current supplied via the bit line BL. The selective element 12 may be connected between the phase changeable element 11 and the word line WL. Current supply to the phase changeable element 11 is controlled in accordance with the voltage of the word line WL. The selective element 12 may be a diode, a MOS transistor, or a bipolar transistor.

The phase changeable element 11 contains a phase-change material. The phase-change material has an amorphous state with relatively high resistance and a crystal state with relatively low resistance in accordance with a temperature and a cooling time. The amorphous state may be a reset state and the crystal sate may be a set state. The phase changeable memory device may generate the Joule's heat in accordance with the amount of current supplied via a lower electrode (or a heating element), and thus may heat the phase-change material by the Joule's heat. At this time, the Joule's heat may be generated in proportion to the non-resistance of the phase-change material and a supply time of current.

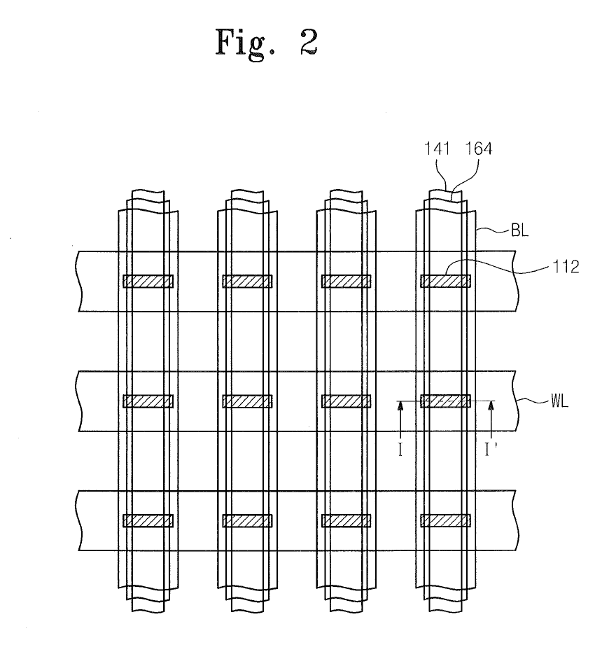

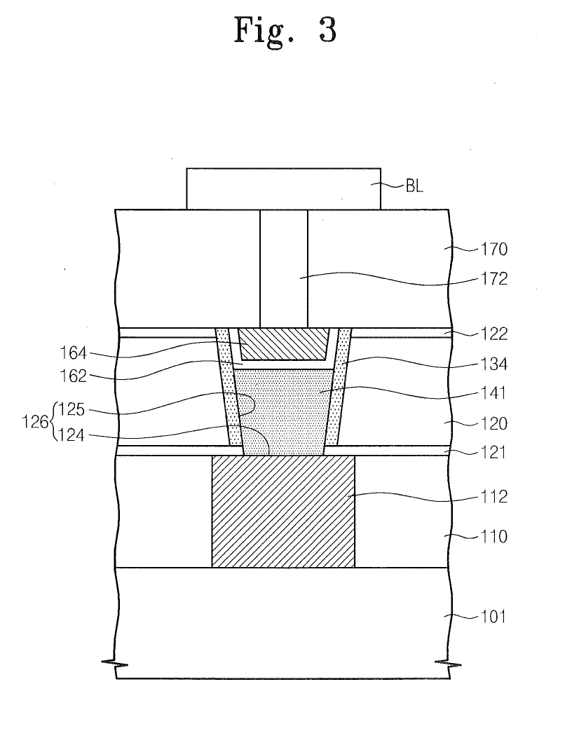

Referring now to FIG. 2 is a diagram illustrating the overall layout of a phase changeable memory device according to some embodiments of the inventive concept. FIG. 3 is a cross-section illustrating the phase changeable memory device taken along the line I-I′ of FIG. 2 according to some embodiments of the inventive concept.

Referring to FIGS. 2 and 3, a first inter-layer insulating layer 110 including lower electrodes 112 is formed on a semiconductor substrate 101. The first inter-layer insulating layer 110 may be a silicon oxide layer (SiO₂). The semiconductor substrate 101 may include the word line WL extending in a first direction. The word line WL may be a doped line doped with impurities. Moreover, the semiconductor substrate 101 may include a selective element connected to the work line WL. The selective element may be electrically connected to the lower electrodes 112. The selective element may be a diode, a MOS transistor, or a bipolar transistor.

Though the case has been described in which the first inter-layer insulating layer 110 including the lower electrodes 112 are formed on the semiconductor substrate 101, the semiconductor substrate 101 may include the first inter-layer insulating layer 110. This is applicable to some embodiments of the inventive concept.

The lower electrodes 112 may be distant from each other in the first direction on the word line WL. The lower electrodes 112 may have a length extending in the first direction. The lower electrodes 112 may be exposed on the upper surface of the first inter-layer insulating layer 110. The lower electrodes 112 may be utilized as heating electrodes. An upper electrode 164 is provided so as to be distant from the lower electrodes 112 and extends in a second direction intersecting the first direction. The lower electrodes 112 and the upper electrode 164 may be formed of a metal material. The lower electrodes 112 may include, for example, titanium nitride (TiN), titanium aluminum nitride (TiAlN), tantalum nitride (TaN), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), titanium tungsten (TiW), titanium aluminum (TiAl), titanium oxynitride (TiON), titanium aluminum oxynitride (TaAION), tungsten oxynitride (WON), tantalum oxynitride (TaON), or a combination thereof.

The upper electrode 164 may include, for example, titanium nitride, titanium aluminum nitride, tantalum nitride, molybdenum nitride, niobium nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, titanium oxynitride, titanium aluminum oxynitride, tungsten oxynitride, tantalum oxynitride, titanium (Ti), tungsten (W), molybdenum (Mo), tantalum (Ta), titanium silicide (TiSi), tantalum silicide (TaSi), graphite, or a combination thereof.

A mold insulating layer 120 is provided on the first inter-layer insulating layer 110 and the lower electrodes 112. The mold insulating layer 120 is provided between the lower electrodes 112 and the bit line BL. The mold insulating layer 120 may be a silicon oxide layer. A first etching stop layer 121 may be interposed between the first inter-layer insulating layer 110 and the mold insulating layer 120. The first etching step layer 121 may expose parts of the lower electrodes 112. A second etching stop layer 122 may further be formed on the mold insulating layer 120. The first etching stop layer 121 and the second etching stop layer 122 may have etching selectivity with respect to other adjacent films (or other layers). The first etching stop layer 121 and the second etching stop layer 122 may contain, for example, silicon oxide (SiOₓ), silicon nitride (SiN), silicon oxynitride (SiON), tantalum carbon nitride (TiCN), titanium oxide (TiO), zirconium oxide (ZrOₓ), magnesium oxide (MgOₓ), hafnium oxide (HfOₓ), or aluminum oxide (AlOₓ).

An opening 126 may be provided in the mold insulating layer 120, the first etching stop layer 121, and the second etching stop layer 122 to expose the lower electrode 112. The opening 126 may extend in the second direction intersecting the first direction. The upper width of the opening 126 may be larger than the lower width of the opening 126. The opening 126 may include a bottom surface 124 exposing the lower electrodes 112 and a side surface 125 extending upwardly from the bottom surface 124. The angle formed between the bottom surface 124 and the side surface 125 may be 90 degrees or more.

A phase-change material layer 141 is formed in the opening 126. The phase-change material layer 141 fills the lower portion of the opening 126 and has the upper surface below the surface of the mold insulating layer 120. The lower surface of the phase-change material 141 may come into contact with the lower electrodes 112. A region, where the phase-change material layer 141 and the lower electrodes 112 come into contact with each other, may be a phase changeable region where a phase change occurs in accordance with the Joule's heat by the current supplied via the lower electrode 112 serving as a heating electrode.

The phase-change material layer 141 may include a chalcogenide material, for example. The chalcogenide material may include at least one of D1-Ge—Sb—Te, D2-Ge—Bi—Te, D3-Sb—Te, D4-Sb—Se, and D5-Sb. Here, D1 may include at least one of carbon (C), nitrogen (N), silicon (Si), bismuth (Bi), indium (In), arsenic (As), and selenium (Se). D2 may include at least one of carbon, nitrogen, silicon, indium, arsenic, and selenium. D3 may include at least one of arsenic, tin (Sn), SnIn, Group 5B element, and Group 6B element. D4 may include at least one of Group 5A element and Group 6A element. D5 may include at least one of germanium (Ge), gallium (Ga), and indium.

The upper electrode 164 is provided on the phase-change material layer 141 in the opening 126. The upper electrode 164 may come into contact with the upper surface of the phase-change material layer 141. A buffer layer 162 may further be provided to prevent the material from diffusing between the phase-change material 141 and the upper electrode 164. The buffer layer 162 may be formed of a material that includes at least one of titanium, tantalum, molybdenum, hafnium (Hf), zirconium (Zr), chromium (Cr), tungsten, niobium (Nb), and vanadium (V) and at least one of nitrogen, carbon, aluminum, boron (B), phosphorous (P), oxygen, and silicon, or a combined material thereof. The buffer layer 162 may include at least one of titanium nitride, titanium tungsten, titanium carbon nitride (TiCN), titanium aluminum nitride, titanium silicon carbide (TiSiC), tantalum nitride, tantalum silicon nitride, tungsten nitride, molybdenum nitride, and carbon nitride (CN), for example. The buffer layer 162 may contain a compound having chemical formula DₐM_{b}Ge (where 0≦a≦0.7 and 0≦b≦0.2). In the chemical formula, D may include at least one of carbon, nitrogen, and oxygen and M may include at least one of transition metal, rare earth metal, noble metal, aluminum (Al), gallium, and indium. Alternatively, the buffer layer 162 may include a compound having chemical formula DₐM_{b}[GₓT_{y}]_{c} (where 0≦a/(a+b+c)≦0.2, 0≦b(a+b+c)≦0.1, and 0.3≦x(x+y)≦0.7). In the chemical formula, D may include at least one of carbon, nitrogen, and oxygen, M may include at least one of transition metal, aluminum, gallium, and indium, G may include germanium, and T may include tellurium (Te). In the chemical formula, Gₓ may be Geₓ₁G′ₓ₂ (0.8≦x1(x1+x2)≦1). G′ may be Group 3A element or Group 5A element. For example, G′ may be aluminum, gallium, indium, silicon, tin, arsenic, antimony (Sb), or bismuth. In the chemical formula, T_{y} may be Te_{y1}Se_{y2} (where 0.8≦y1(y1+y2)≦1). The buffer layer 162 contains germanium or tellurium relatively much than Ge—Sb—Te, which is a general phase-change material. The upper electrode 164 may have a line shape intersecting the word line WL. The upper electrode 164 with the line shape may be utilized as the bit line BL.

A spacer 134 is provided on the side surface 125 of the opening 126. The spacer 134 is distant from the lower electrodes 112 between the sidewall of the mold insulating layer 120, and the phase-change material layer 141 and the upper electrode 164. The spacer 134 may prevent the material from diffusing between the phase-change material layer 141 and the mold insulating layer 120. The spacer 134 may include, for example, silicon oxide, silicon nitride, silicon oxynitride, tantalum carbon nitride, titanium oxide, zirconium oxide, magnesium oxide, hafnium oxide, or aluminum oxide.

Accordingly, the phase-change material layer 141 and the upper electrode 164 may completely fill the opening 126 of the mold insulating layer 120, and thus may have a form confined in the opening 126. Upper surfaces of the mold insulating layer 120 (or the second etching stop layer 122), the spacer 134, and the upper electrode 164 may have a flat coplanar surface.

The bit line BL may be provided on the upper electrode 164 so as to intersect the word line WL. The bit line BL may be electrically connected to the upper electrode 164 via a contact plug 172 of a second inter-layer insulating layer 170.

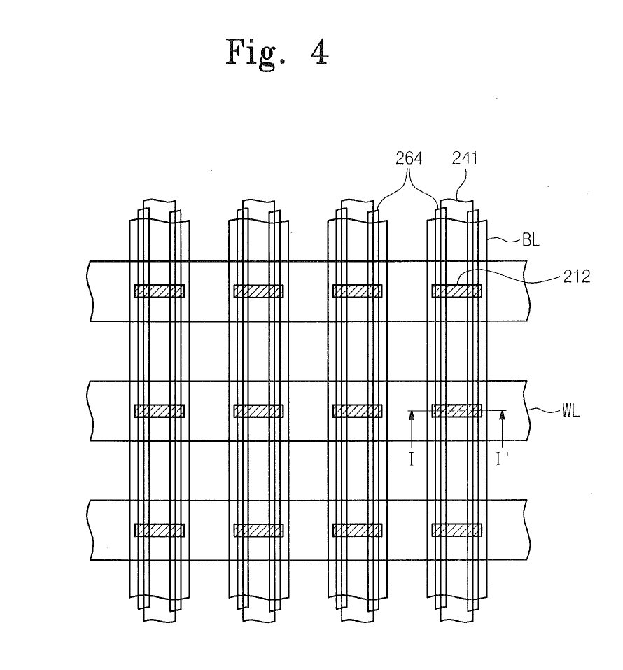

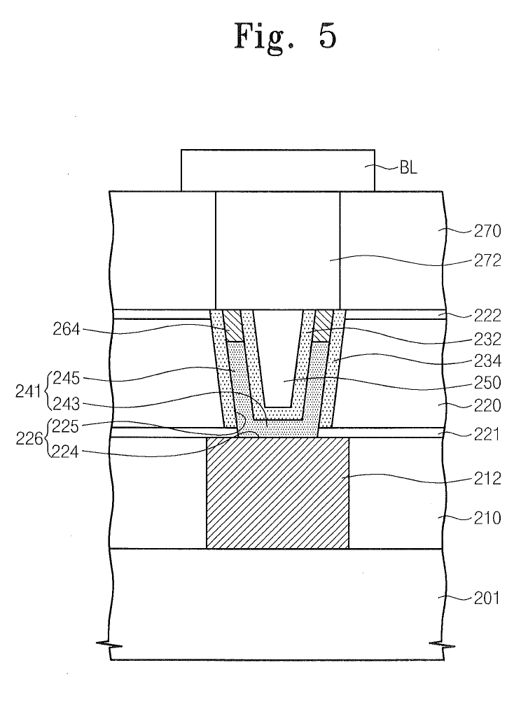

FIG. 4 is a diagram illustrating the overall layout of a phase changeable memory device according to some embodiments of the inventive concept. FIG. 5 is a cross-section illustrating the phase changeable memory device taken along the line I-I′ of FIG. 4 in accordance with some embodiments of the inventive concept. The similar reference numerals are given to substantially the same elements as those of embodiments discussed above with respect to FIGS. 2 and 3 and, therefore, detailed description of the these features will not be repeated in the interest of brevity.

Referring now to FIGS. 4 and 5, a phase-change material layer 241 is provided in an opening 226. The phase-change material layer 241 may include a bottom portion 243, which comes into contact with lower electrodes 212, and a sidewall portion 245, which extends upwardly from both ends of the bottom 243. The sidewall portion 245 has an upper surface below the surface of a mold insulating layer 220. The bottom portion 243 is provided on a bottom surface 224 of the opening 226 and the sidewall portion 245 is provided on a side surface 225 of the opening 226. The bottom portion 243 comes into contact with the lower electrodes 212, and the sidewall portion 245 extends from the bottom portion 243 to an upper electrode 264. Therefore, the phase-change material layer 241 may have a U-shaped cross-section. Regions, where the phase-change material layer 241 and the lower electrodes 212 come into contact with each other, may be phase changeable regions where a phase change occurs in accordance with the Joule's heat by the current supplied via the lower electrodes 212 serving as heating electrodes.

An upper electrode 264 is provided on the sidewall portion 245 of the phase-change material layer 241 in the opening 226. The upper electrode 264 may come into contact with the upper surface of the sidewall portion 245 of the phase-change material layer 242. The upper electrode 264 may have a line shape intersecting the word line WL. The upper electrode 264 with the line shape may be utilized as the bit line BL.

A protective layer 232 is formed to expose a upper surface of the upper electrode 264 and to cover the inner surface of the upper electrode 264 and the phase-change material layer 241 exposed to an inner space (see reference numeral 229 in FIG. 29) formed by the upper electrode 264, the bottom portion 243 of the phase-change material layer 241 and the sidewall portion 245 of the phase-change material layer 241. The inner space may be partially filled with the protective layer 232. The protective layer 232 may prevent the material from diffusing between the phase-change material layer 241 and a gap-fill insulating layer 250. The protective layer 232 may include, for example, silicon oxide, silicon nitride, silicon oxynitride, tantalum carbon nitride, titanium oxide, zirconium oxide, magnesium oxide, hafnium oxide, or aluminum oxide.

A gap-fill insulting layer 250 may be provided on the protective layer 232 so as to completely fill the inner space. The gap-fill insulating layer 250 may include a silicon oxide layer with a god gap-fill characteristic, such as HDP (high density plasma) silicon oxide, PE-TEOS (Plasma-Enhanced TetraEthylOrthoSilicate), BPSG (BoroPhosphoSilicate Glass), USG (Undoped Silicate Glass), FOX (Flowable Oxide), HSQ (HydroSilsesQuioxane) or SOG (Spin On Glass). The gap-fill insulating layer 250 may be a silicon nitride layer or a silicon oxynitride layer. The gap-fill insulating layer 250 may expose the upper surface of the upper electrode 264.

Therefore, the phase-change material layer 241 and the upper electrode 264 may have a form confined in the opening 226 of the mold insulating layer 220 by the gap-fill insulating layer 250. Upper surfaces of the gap-fill insulating layer 250, the protective layer 232, the upper electrode 264, a spacer 234, and the mold insulating layer 220 (or the second etching stop layer 222) may have a flat coplanar surface.

A bit line BL may be provided on the upper electrode 264 to intersect the word line WL. The bit line BL may be electrically connected to a pair of upper electrodes 264 via a contact plug 272 of a second inter-layer insulating layer 270.

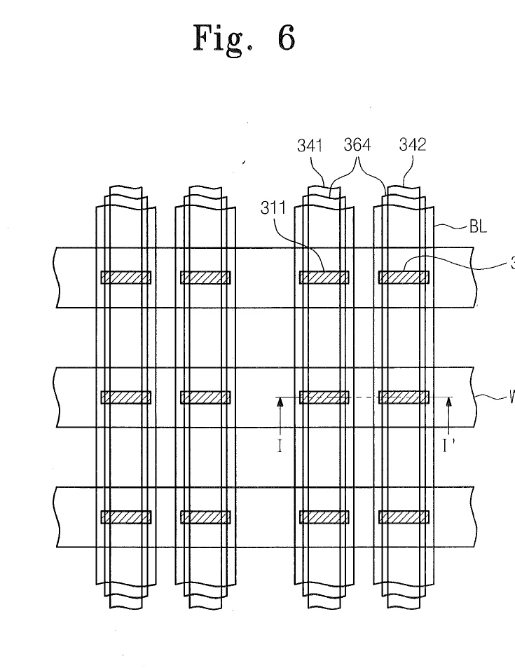

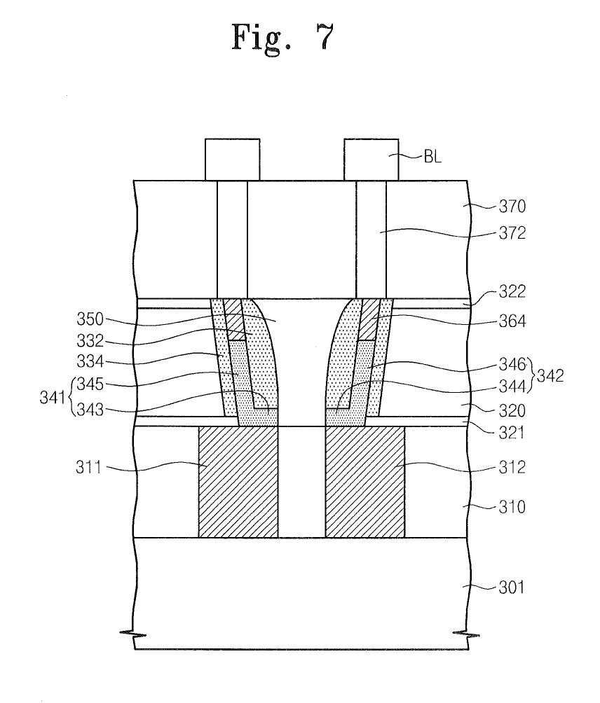

FIG. 6 is a diagram illustrating the overall layout of a phase changeable memory device according to some embodiments of the inventive concept. FIG. 7 is a cross-section illustrating the phase changeable memory device taken along the line I-I′ of FIG. 6 in accordance with some embodiments of the inventive concept. As illustrated in FIGS. 6 and 7, a first inter-layer insulating layer 310 including one pair of lower electrodes 311 and 312 distant from each other is formed on a semiconductor substrate 301. The first inter-layer insulating layer 310 may be a silicon oxide layer. The semiconductor substrate 301 may include a word line WL extending in the first direction. The word line WL may be a doped line doped with impurities. Moreover, the semiconductor substrate 301 may include a selective element connected to the word line WL. The selective element may be electrically connected to the lower electrodes 311 and 312. The selective element may be a diode, a MOS transistor, or a bipolar transistor.

The pair of the lower electrodes 311 and 312 may be distant from each other in the first direction on the word line WL. The lower electrodes 311 and 312 may have lengths extending in the first direction. The lower electrodes 311 and 312 may be exposed on the upper surface of the first inter-layer insulating layer 310. The lower electrodes 311 and 312 may be utilized as heating electrodes. The lower electrodes 311 and 312 may include a first lower electrode 311 and a second lower electrode 312. An upper electrode 364 extending in the second direction intersecting the first direction is provided to face one pair of the lower electrodes 311 and 312 and to de distant from the lower electrodes 311 and 312. The lower electrodes 311 and 312 and the upper electrode 364 may be formed of a metal material. The metal material may include the materials mentioned in the embodiments of the inventive concept discussed above.

A mold insulating layer 320 is provided on the first inter-layer insulating layer 310 and the lower electrodes 311 and 312. The mold insulating layer 320 may be provided between the first electrodes 311 and 312 and the bit lines BL. The mold insulating layer 320 may be a silicon oxide layer. A first etching stop layer 321 may be interposed between the first inter-layer insulating layer 310 and the mold insulating layer 320. The first etching step layer 321 may expose a portion of the lower electrodes 311 and 312. A second etching stop layer 322 may further be provided on the mold insulating layer 320. The first etching stop layer 321 and the second etching stop layer 322 may have etching selectivity with respect to other adjacent films (or other layers). The first etching stop layer 321 and the second etching stop layer 322 may include, for example, silicon oxide, silicon nitride, silicon oxynitride, tantalum carbon nitride, titanium oxide, zirconium oxide, magnesium oxide, hafnium oxide, or aluminum oxide.

An opening 326 is provided in the mold insulating layer 320, the first etching stop layer 321, and the second etching stop layer 322 to expose one pair of lower electrodes 311 and 312. The opening 326 may extend in the second direction intersecting the first direction. The upper width of the opening 326 may be larger than the lower width of the opening 326. The opening 326 may include a bottom surface 324 exposing the lower electrodes 311 and 312 and a side surface 325 extending upwardly from the bottom surface 324. The angle formed between the bottom surface 324 and the side surface 325 may be 90 degrees or more.

Phase-change material layers 341 and 342 are provided in the opening 326. The phase-change material layers 341 and 342 may include a first phase-change material layer 341 and a second phase-change material layer 342. The first phase-change material layer 341 may include a first bottom portion 343 coming into contact with the first lower electrode 311 and a first sidewall portion 345 extending from one end of the first bottom portion 343 to the upper electrode 364. The first bottom portion 343 and the first sidewall portion 345 may form an L-shaped cross-section. The second phase-change material layer 342 may include a second bottom portion 344 coming into contact with the second lower electrode 312 and a second sidewall portion 346 extending from one end of the second bottom portion 344 to the upper electrode 364. The second bottom portion 344 and the second sidewall portion 346 may form an L-shaped cross-section. The bottom portions 343 and 344 may be provided on the bottom surface 324 of the opening 326 and the sidewall portions 345 and 346 may be provided on the sidewalls 325 of the opening 326. The first phase-change material layer 341 and the second phase-change material layer 342 may have an L-shaped cross-section. The first sidewall portion 345 and the second sidewall portion 346 may have an upper surface below the surface of the mold insulating layer 320. The first phase-change material layer 341 and the second phase-change material layer 342 may be provide so as to face to each other in a mirror form. The term “facing” may mean that the other end of the first bottom portion 343 and the other end of the second bottom portion 344 are adjacent to each other. Regions, where the phase-change material layers 341 and 342 and the lower electrodes 311 and 312 come into contact with each other, may be phase changeable regions where a phase change occurs in accordance with the Joule's heat by the current supplied via the lower electrodes 311 and 312 serving as heating electrodes.

The phase-change material layers 341 and 342 may include a phase-change material such as a chalcogenide material, as in the embodiments of the inventive concept discussed above.

An upper electrode 364 is provided on the phase-change material layers 341 and 342 in the opening 326. The upper electrode 364 may come into contact with the upper surfaces of the phase-change material layers 341 and 342. The upper electrode 364 may a have a line shape intersecting the word line WL. The upper electrode 364 with the line shape may be utilized as the bit lines BL.

A spacer 334 is provided on the side surface 325 of the opening 326 so that the spacer 334 is distant from the lower electrodes 311 and 312 and is provided between the sidewall of the mold insulating layer 320, and the phase-change material layer 341 and the upper electrode 364. The spacer 334 may prevent the material from diffusing between the phase-change material layer 341 and the mold insulating layer 320. The spacer 334 may include the material mentioned in some embodiment of the inventive concept discussed above.

A protective layer 332 is formed to cover the upper surfaces of the bottom portions 343 and 344 of the phase-change material layers 341 and 342, the sidewall portions 345 and 346 of the phase-change material layers 341 and 342, and the inner surface of the upper electrode 364 and to expose the upper surface of the upper electrode 364. The protective layer 332 may have a spacer form covering the upper surfaces of the bottom portions 343 and 344 of the phase-change material layers 341 and 342, the sidewall portions 345 and 346 of the phase-change material layers 341 and 342, and the inner surface of the upper electrode 364. The lower portion of the protective layer 332 may be aligned with the other ends of the bottom portions 343 and 344. The upper portion of the protective layer 332 may have a coplanar surface with the upper surface of the upper electrode 364. The protective layer 332 may prevent the material from diffusing between the phase-change material layers 341 and 342 and a gap-fill insulating layer 350. The protective layer 332 may include the material mentioned in some embodiments of the inventive concept discussed above.

A gap-fill insulting layer 350 may be provided between the protective layers 332 so as to completely fill the remaining space of the opening 326. The gap-fill layer 350 may include the material mentioned in some embodiments of the inventive concept discussed above. The gap-fill insulating layer 350 may expose the upper surface of the upper electrode 364.

Therefore, the phase-change material layers 341 and 342 and the upper electrode 364 may have a form confined in the opening 326 of the mold insulating layer 320 by the protective layer 332 and the gap-fill insulating layer 350. Upper surfaces of the gap-fill insulating layer 350, the protective layer 332, the upper electrode 364, the spacer 334, and the mold insulating layer 320 (or the second etching stop layer 322) may have a flat coplanar surface.

The bit line BL may be provided on the upper electrode 364 so as to intersect the word line WL. The bit line BL may be electrically connected to a pair of upper electrodes 364 via a contact plug 372 of a second inter-layer insulating layer 370.

When current flows in the first phase-change material layer 341 and the second phase-change material layer 342 via the lower electrodes 311 and 312, respectively, a phase change may occur in the phase changeable regions. According to some embodiments of the inventive concept, since the first phase-change material layer 341 and the second phase-change material layer 342 have the L-shaped cross-section, it is possible to reduce the area of the bottom portions 343 and 344 of the phase-change material layers 341 and 342 coming into contact with the lower electrodes 311 and 312 and it is possible to reduce the volume of the phase-change material layers 341 and 342. Therefore, driving current can be reduced which is necessary to change the state of the first phase-change material layer 341 and the second phase-change material layer 342.

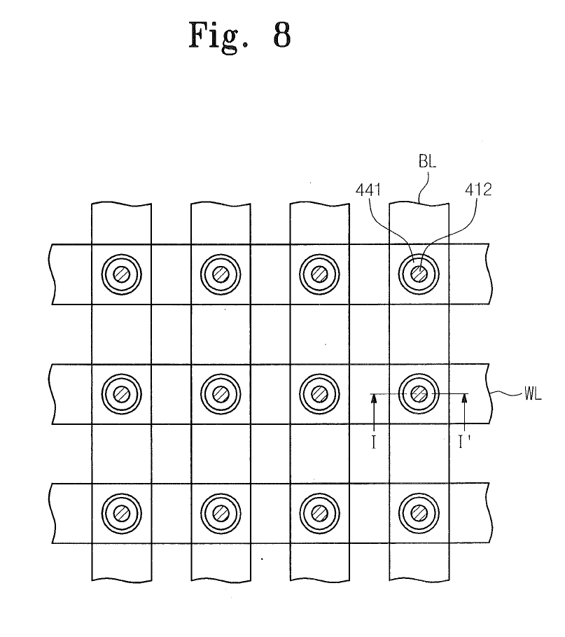

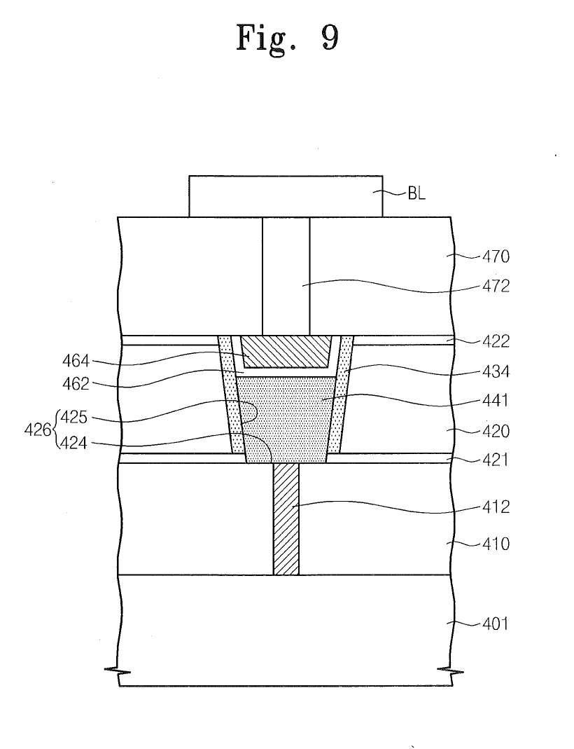

FIG. 8 is a diagram illustrating the overall layout of a phase changeable memory device according to some embodiments of the inventive concept. FIG. 9 is a cross-section illustrating the phase changeable memory device taken along the line I-I′ of FIG. 8 in accordance with some embodiments of the inventive concept.

Referring to FIGS. 8 and 9, a first inter-layer insulating layer 410 including lower electrodes 412 including lower electrodes 412 is provided on a semiconductor substrate 401. The first inter-layer insulating layer 410 may be a silicon oxide layer. The semiconductor substrate 401 may include a word line WL extending in the first direction. The word line WL may be a doped line doped with impurities. Moreover, the semiconductor substrate 401 may include a selective element connected to the word line WL. The selective element may be electrically connected to the lower electrodes 412. The selective element may be a diode, a MOS transistor, or a bipolar transistor.

The lower electrodes 412 may be distant from each other in the first direction on the word line WL. The lower electrodes 412 may have a columnar shape. The lower electrodes 412 may be exposed on the upper surface of the first inter-layer insulating layer 410. The lower electrodes 412 may be utilized as heating electrodes. An upper electrode 464 is disposed so as to be distant from the lower electrodes 412. The lower electrodes 412 and the upper electrode 464 may be formed of a metal material. The metal material may include the materials mentioned in some embodiments of the inventive concept discussed above.

A mold insulating layer 420 is provided on the first inter-layer insulating layer 410 and the lower electrodes 412. The mold insulating layer 420 is provided between the first electrodes 412 and the bit line BL. The mold insulating layer 420 may be a silicon oxide layer. A first etching stop layer 421 may be interposed between the first inter-layer insulating layer 410 and the mold insulating layer 420. The first etching step layer 421 may expose a portion of the first electrodes 412. A second etching stop layer 422 may further be provided on the mold insulating layer 420. The first etching stop layer 421 and the second etching stop layer 422 may have etching selectivity with respect to other adjacent films (or other layers). The first etching stop layer 421 and the second etching stop layer 422 may include the materials mentioned in some embodiments of the inventive concept discussed above.

An opening 426 may be provided in the mold insulating layer 420, the first etching stop layer 421, and the second etching stop layer 422 to expose the lower electrode 412. The opening 426 may be provided on the position corresponding to the lower electrode 412. The upper width of the opening 426 may be larger than the lower width of the opening 426. The opening 426 may include a bottom surface 424 exposing the lower electrodes 412 and a side surface 425 extending upwardly from the bottom surface 424. The angle formed between the bottom surface 424 and the side surface 425 may be 90 degrees or more.

A phase-change material layer 441 is provided in the opening 426. The phase-change material layer 441 may fill the lower portion of the opening 426 and may have the upper surface below the surface of the mold insulating layer 420. The lower surface of the phase-change material 441 may come into contact with the lower electrodes 412. A region, where the phase-change material layer 441 and the lower electrodes 412 come into contact with each other, may be a phase changeable region where a phase change occurs in accordance with the Joule's heat by the current supplied via the lower electrode 412 serving as a heating electrode.

The phase-change material layer 441 may include a phase-change material such as a chalcogenide material, as in the above-described embodiments of the inventive concept.

An upper electrode 464 is provided on the phase-change material layer 441 in the opening 426. The upper electrode 464 may come into contact with the upper surface of the phase-change material layer 441. A buffer layer 462 may further be provided to prevent the material from diffusing between the phase-change material 441 and the upper electrode 464. The buffer layer 462 may include the materials mentioned in the some of the inventive concept discussed above.

A spacer 434 is provided on the side surface 425 of the opening 426 to be distant from the lower electrodes 412 between the sidewall of the mold insulating layer 420, and the phase-change material layer 441 and the upper electrode 464. The spacer 434 may prevent the material from diffusing between the phase-change material layer 441 and the mold insulating layer 420. The spacer 434 may contain the materials mentioned in some embodiments of the inventive concept discussed above.

Accordingly, the phase-change material layer 441 and the upper electrode 464 completely may fill the opening 426 of the mold insulating layer 420, and thus may have a form confined in the opening 426. Upper surfaces of the mold insulating layer 420 (or the second etching stop layer 422), the spacer 434, and the upper electrode 464 may have a flat coplanar surface.

A bit line BL may be provided on the upper electrode 464 so as to intersect the word line WL. The bit line BL may be electrically connected to the upper electrode 464 via a contact plug 472 of a second inter-layer insulating layer 470.

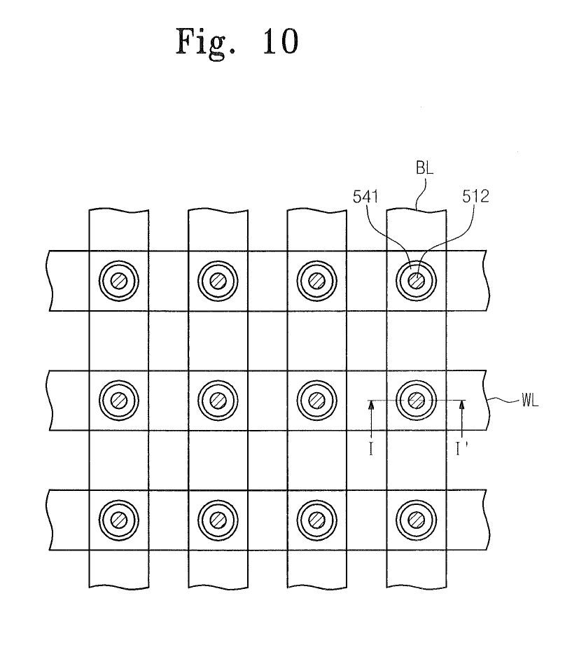

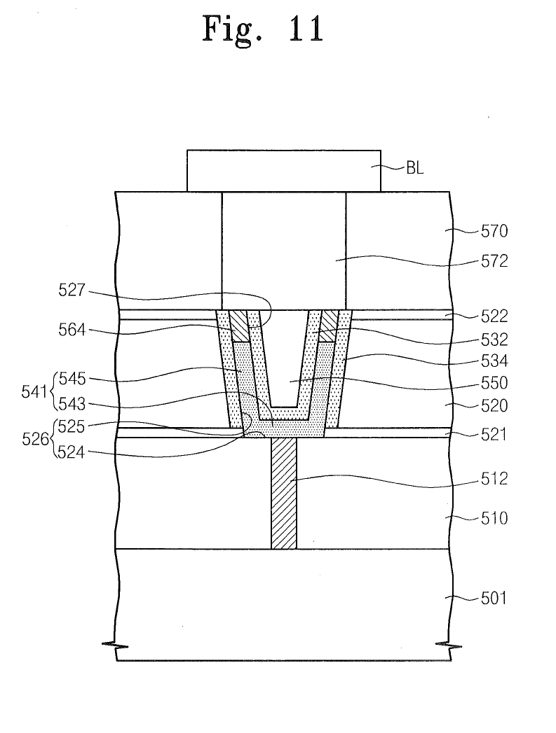

FIG. 10 is a diagram illustrating the overall layout of a phase changeable memory device according to some embodiments of the inventive concept. FIG. 11 is a cross-section illustrating the phase changeable memory device taken along the line I-I′ of FIG. 10 according to some embodiments of the inventive concept. The similar reference numerals are given to substantially the same elements as those of embodiments discussed above with respect to FIGS. 8 and 9 and, therefore, description of these features will not be repeated herein in the interest of brevity.

Referring now to FIGS. 10 and 11, a phase-change material layer 541 is provided in an opening 526. The phase-change material layer 541 may include a bottom portion 543, which comes into contact with lower electrodes 512, and a sidewall portion 545, which extends upwardly from both ends of the bottom 543. The sidewall portion 545 may have an upper surface below the surface of a mold insulating layer 520. The bottom portion 543 may be provided on a bottom surface 524 of the opening 526 and the sidewall portion 545 may be provided on a side surface 525 of the opening 526. The bottom portion 543 may come into contact with the lower electrodes 512, and the sidewall portion 545 may extend from the bottom portion 543 to an upper electrode 564. Therefore, the phase-change material layer 541 may have a U-shaped cross-section. A region, where the phase-change material layer 541 and the lower electrodes 512 come into contact with each other, may be a phase changeable region where a phase change occurs in accordance with the Joule's heat by the current supplied via the lower electrode 512 serving as a heating electrode.

An upper electrode 564 is provided on the sidewall portion 545 of the phase-change material layer 541 in the opening 526. The upper electrode 564 may come into contact with the upper surface of the sidewall portion 545 of the phase-change material layer 542.

A protective layer 532 is provided to expose a upper surface of the upper electrode 564 and to cover the inner surface of the upper electrode 564 and the phase-change material layer 541 exposed to an inner space formed by the upper electrode 564, the bottom portion 543 of the phase-change material layer 541 and the sidewall portion 545 of the phase-change material layer 541. The inner space may be partially filled with the protective layer 532. The protective layer 532 may prevent the material from diffusing between the phase-change material layer 541 and a gap-fill insulating layer 550. The protective layer 532 may provided the materials mentioned in some embodiments of the inventive concept discussed above.

The gap-fill insulting layer 550 is provided on the protective layer 532 so as to completely fill the inner space. The gap-fill insulating layer 550 may include the materials mentioned in some embodiments of the inventive concept discussed above. The gap-fill insulating layer 550 may expose the upper surface of the upper electrode 564.

Therefore, the phase-change material layer 541 and the upper electrode 564 may have a form confined in the opening 526 of the mold insulating layer 520 by the gap-fill insulating layer 550. Upper surfaces of the gap-fill insulating layer 550 (or the second etching stop layer 522), the protective layer 532, the upper electrode 564, a spacer 534, and the mold insulating layer 520 may have a flat coplanar surface.

The bit line BL may be provided on the upper electrode 564 to intersect the word line WL. The bit line BL may be electrically connected to a pair of upper electrodes 564 via a contact plug 572 of a second inter-layer insulating layer 570.

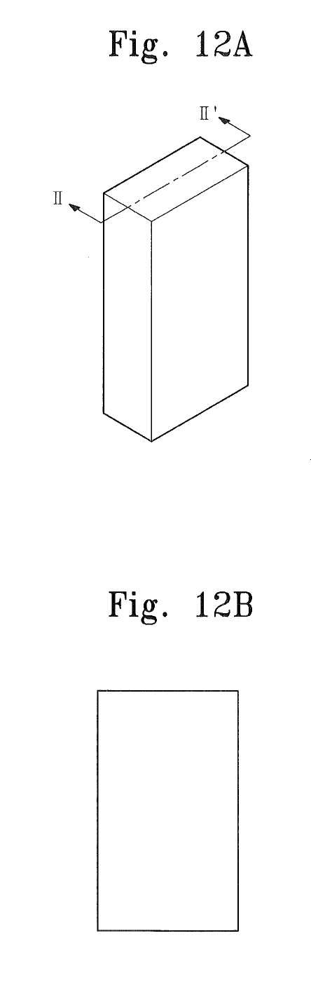

FIGS. 12A through 15B are diagrams illustrating examples of a lower electrode of the phase changeable memory device according to some embodiments of the inventive concept. FIGS. 12A, 13A, 14A, and 15A are perspective views illustrating the lower electrodes. FIGS. 12B, 13B, 14B, and 15B are cross-sections taken along the lines II-II′ of FIGS. 12A, 13A, 14A, and 15A, respectively.

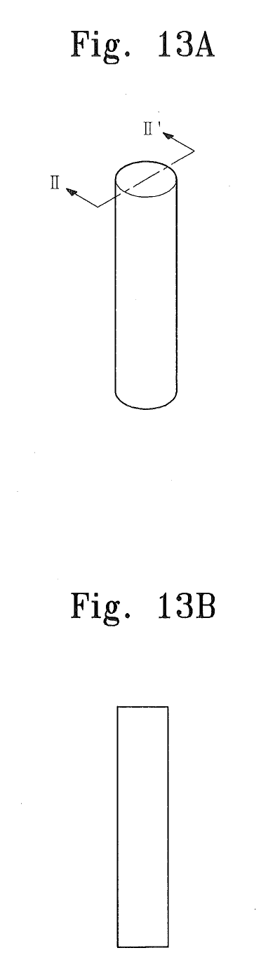

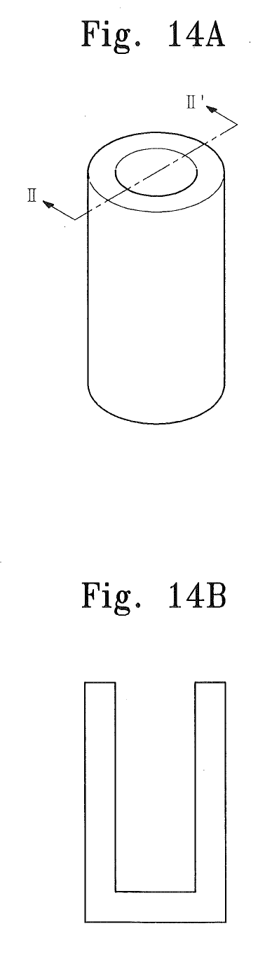

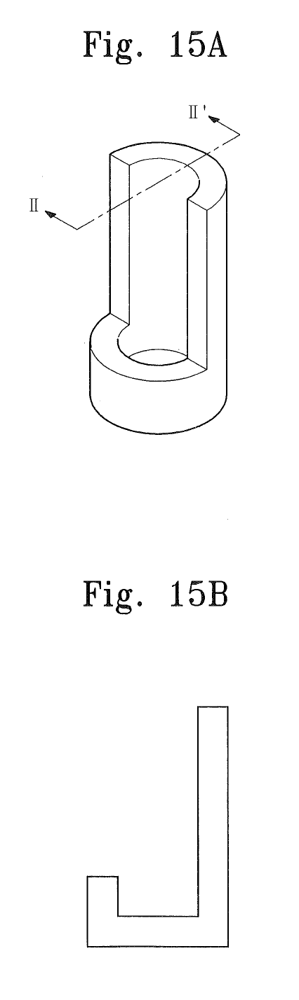

Referring to FIGS. 12A through 15B, the lower electrodes are described as a form having a length extending in one direction, a cylindrical shape, or a columnar shape in the above-described embodiments of the inventive concept. However, the inventive concept is not limited thereto. FIGS. 12A and 12B show a line shape extending in one direction. FIGS. 13A and 13B show a columnar shape. FIGS. 14A and 14B illustrate a cylindrical shape (of which the lower portion is closed and the upper portion is opened). FIGS. 15A and 15B show an arc shape (of which the lower portion is cylindrical and the upper portion is semi-circular).

The phase changeable memory device according to some embodiments of the inventive concept may have the configuration in which the phase-change material layer and the upper electrode are confined in the opening of the mold insulating layer. Due to such a configuration, since photolithography and etching are omitted upon forming the upper electrode, the phase-change material layer may not be damaged. Accordingly, it is possible to improve reliability of the phase changeable memory device. Moreover, since a misalign problem may be solved between the phase-change material layer and the upper electrode, it is possible to form the phase changeable memory device by the easy process.

The phase changeable memory device according to some embodiments of the inventive concept may have the configuration in which the spacer is interposed between the mold insulating layer, and the phase-change material layer and the upper electrode layer. Due to such a configuration, since it is possible to adjust the contact length (or the area) between the lower electrode and the phase-change material layer, a high integrated phase changeable memory device can be realized.

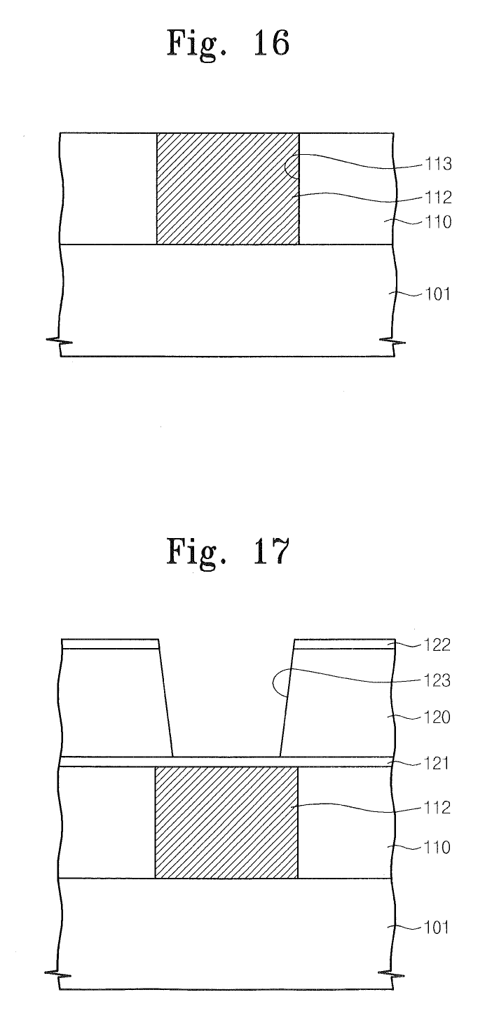

FIGS. 16 to 25 are cross-sections taken along the line I-I′ of FIG. 2 illustrating processing steps in the fabrication of phase changeable memory device according to some embodiments of the inventive concept. As illustrated in FIG. 16, a semiconductor substrate 101 is prepared. The semiconductor substrate 101 may include a p-type silicon substrate and/or an insulating layer on the p-type silicon substrate. The word line WL (see FIG. 2) may be formed in the semiconductor substrate 101 to extend in the first direction. For example, the word line may be formed by doping impurities in the semiconductor substrate 101. Moreover, the selective element may be formed in the semiconductor substrate 101 so as to be connected to the word line. The selective element may be a diode, a MOS transistor, or a bipolar transistor.

A first inter-layer insulating layer 110 is formed on the semiconductor substrate 101. The first inter-layer insulating layer 110 may be a silicon oxide layer. A through hole 113 may be formed in the first inter-layer insulating layer 110. The through hole 113 may be filled with a conductive material. A planarization process may be performed on the conductive material to form the lower electrodes 112 in the first inter-layer insulating layer 110. The lower electrodes 112 may be exposed on the upper surface of the first inter-layer insulating layer 110. The planarization process may be chemical mechanical polishing (CMP). The forming order of the first inter-layer insulating layer 110 and the lower electrodes 112 may be different from the above order. For example, the conductive material may be formed on the semiconductor substrate 101, the conductive material may be patterned to form the lower electrodes 112, the first inter-layer insulating layer 110 may be formed to cover the lower electrodes 112, and then the first inter-layer insulating layer 110 may be patterned to expose the lower electrodes 112. The lower electrodes 112 including the conductive material may be utilized as heating electrodes of the phase changeable memory device.

The lower electrodes 112 may contain, for example, titanium nitride, titanium aluminum nitride, tantalum nitride, tungsten nitride, molybdenum nitride, niobium nitride, titanium silicon nitride, titanium boron nitride, zirconium silicon nitride, tungsten silicon nitride, tungsten boron nitride, zirconium aluminum nitride, molybdenum aluminum nitride, tantalum silicon nitride, tantalum aluminum nitride, titanium tungsten, titanium aluminum, titanium oxynitride, titanium aluminum oxynitride, tungsten oxynitride, tantalum oxynitride, or a combination thereof.

The lower electrodes 112 may be electrically connected to the selective element. The lower electrodes 112 may be distant from each other in the first direction on the word line. In FIG. 16, the lower electrodes 112 illustrated in FIGS. 12A and 12B are illustrated, but the inventive concept is not limited thereto.

Referring to FIG. 17, the mold insulating layer 120 is formed on the first inter-layer insulating layer 110 and the lower electrodes 112. The mold insulating layer 120 may be a silicon oxide layer. Before the mold insulating layer 120 is formed, a first etching stop layer 121 may further be formed. A second etching stop layer 122 may further be formed on the mold insulating layer 120. The first etching stop layer 121 and the second etching stop layer 122 may have etching selectivity with respect to other adjacent films (or layers). The first etching stop layer 121 and the second etching stop layer 122 may contain, for example, silicon oxide, silicon nitride, silicon oxynitride, tantalum carbon nitride (TiCN), titanium oxide, zirconium oxide, magnesium oxide, hafnium oxide, or aluminum oxide.

A preliminary opening 123 is formed in the second etching stop layer 122 and the mold insulating layer 120 to expose the first etching stop layer 121. The preliminary opening 123 may overlap with the lower electrodes 112. The preliminary opening 123 may extend in the second direction intersecting the first direction. The upper width of the preliminary opening 123 may be larger than the lower width of the opening 126.

Referring to FIG. 18, a spacer 134 may be formed on a sidewall of the preliminary opening 123. The forming of the spacer 134 may include forming a spacer material layer covering the sidewall of the preliminary opening 123 and the upper surface of the mold insulating layer 120. The spacer 134 may be formed on the sidewall of the preliminary opening 123 by performing an anisotropic etching process to the spacer material layer. The lower electrodes 112 may be exposed by etching the first etching stop layer 121 using the spacer 134 as an etching mask. The forming of the spacer 134 and the forming of the first etching stop layer 121 may be performed simultaneously or continuously.

The spacer 134 may prevent the material from diffusing between the phase-change material layer and the mold insulating layer 120, which are subsequently formed. The spacer 134 may contain, for example, silicon oxide, silicon nitride, silicon oxynitride, titanium carbon nitride, titanium oxide, zirconium oxide, magnesium oxide, hafnium oxide, or aluminum oxide.

As a consequence, a opening 126 is formed in the mold insulating layer 120, the first etching stop layer 121, and the second etching stop layer 122 to expose the lower electrodes 112. The opening 126 may extend in the second direction intersecting the first direction. The upper width of the opening 126 may be larger than the lower width of the opening 126. The opening 126 may include the bottom surface 124 exposing the lower electrodes 112 and the side surface 125 extending upwardly from the bottom surface 124. The angle formed between the bottom surface 124 and the side surface 125 may be 90 degrees or more.

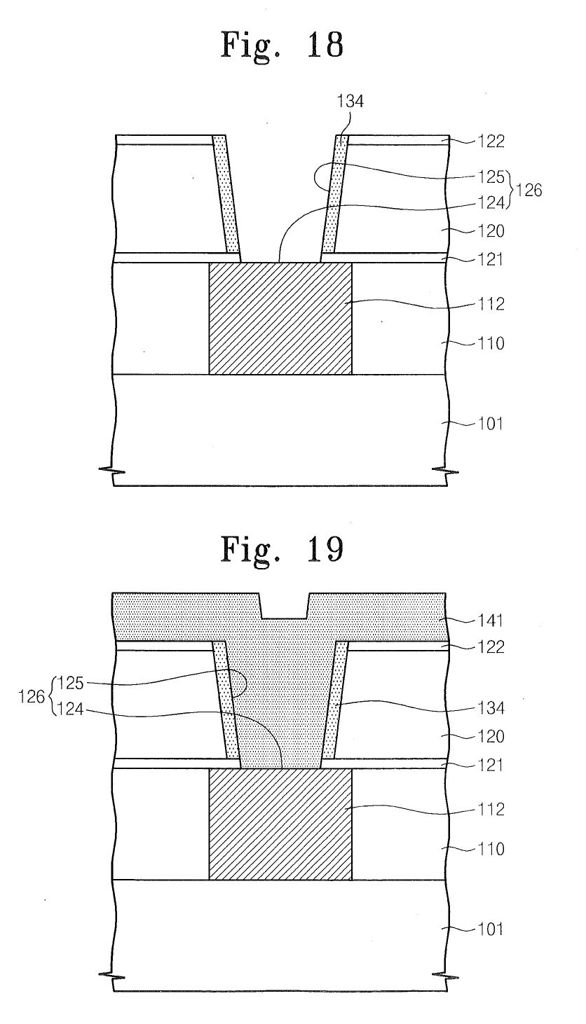

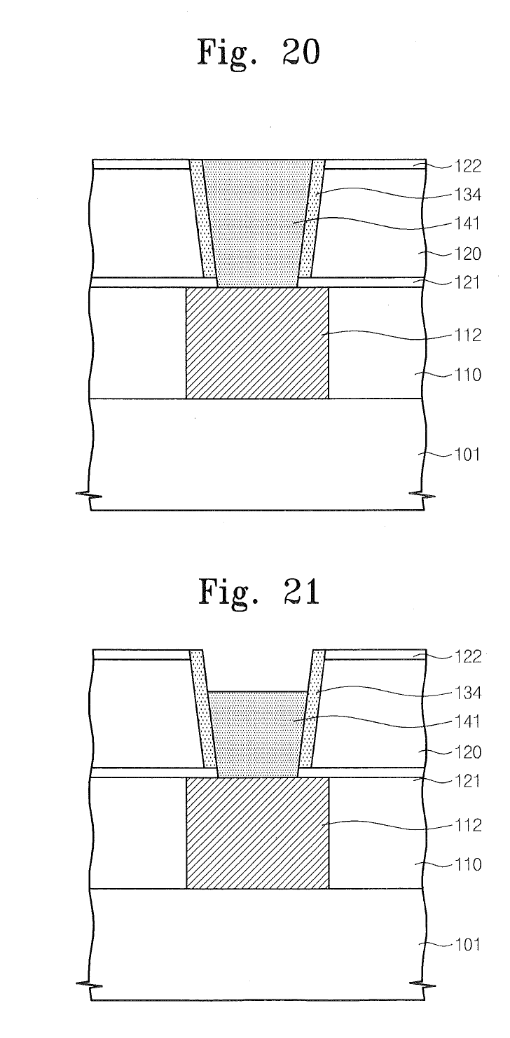

Referring to FIGS. 19 to 21, a phase-change material film may be formed to cover the surface of the mold insulating layer 120, while filling the opening 126. A planarization process may be performed to the phase-change material film to form a phase-change material layer 141. The planarization process may be chemical mechanical polishing process. The second etching stop layer 122 may function as an etching stop layer in the planarization process. Upper surfaces of the spacer 134 and the phase-change material layer 141 may have the flat coplanar surface, as shown in FIG. 20, by the planarization process. Therefore, the phase-change material layer 141 may have a cross-section of a tetragonal shape (such as an isosceles trapezoid shape) and may extend in the second direction in the opening 126. After the planarization process, the upper surface of the phase-change material layer 141 is lowered below the surface of the mold insulating layer 120 by performing a selective etching process. The selective etching process may be reactive ion etching (RIE) of using RF power.

The phase-change material layer 141 may include a chalcogenide material, for example. The chalcogenide material may include at least one of D1-Ge—Sb—Te, D2-Ge—Bi—Te, D3-Sb—Te, D4-Sb—Se, and D5-Sb. Here, D1 may include at least one of carbon, nitrogen, silicon, bismuth, indium, arsenic, and selenium. D2 may include at least one of carbon, nitrogen, silicon, indium, arsenic, and selenium. D3 may include at least one of arsenic, tin, SnIn, Group 5B element, and Group 6B element. D4 may include at least one of Group 5A element and Group 6A element. D5 may include at least one of germanium, gallium, and indium.

The lower surface of the phase-change material layer 141 may come into contact with the lower electrodes 112. The region, where the phase-change material layer 141 and the lower electrodes 112 come into contact with each other, may be the phase changeable region where a phase change occurs in accordance with the Joule's heat by the current supplied via the lower electrode 112 serving as a heating electrode.

After the phase-change material layer 141 is formed, a plasma process may further be performed using an inert gas. The plasma process may remove damage or contamination occurring in the upper surface of the phase-change material layer 141 by reactive ion etching. Examples of the inert gas may include argon (Ar), helium (He), neon (Ne), kypton (Kr) and xenon (Xe).

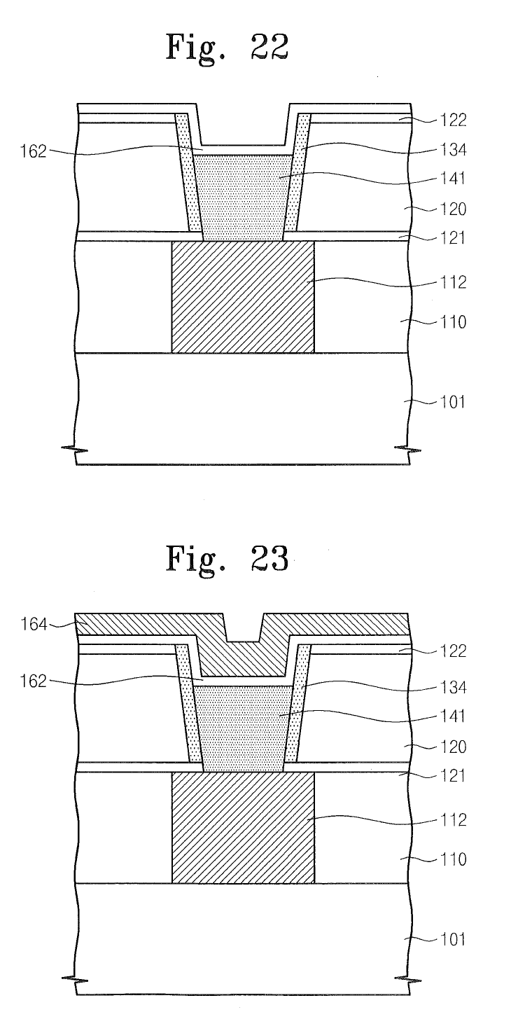

Referring to FIG. 22, a buffer layer 162 may further be formed on the phase-change material 141 in the opening 126. The buffer layer 162 prevents the material from diffusing between the phase-change material layer 141 and the upper electrode, which is formed later. The buffer layer 162 may be formed of a material that includes at least one of titanium, tantalum, molybdenum, hafnium, zirconium, chromium, tungsten, niobium, and vanadium and at least one of nitrogen, carbon, aluminum, boron, phosphorous, oxygen, and silicon, or a combined material thereof. The buffer layer 162 may include at least one of titanium nitride, titanium tungsten, tantalum carbon nitride, titanium aluminum nitride, titanium silicon carbide, tantalum nitride, tantalum silicon nitride, tungsten nitride, molybdenum nitride, and carbon nitride, for example. The buffer layer 162 may include a compound having chemical formula DₐM_{b}Ge (where 0≦a≦0.7 and 0≦b≦0.2). In the chemical formula, D may include at least one of carbon, nitrogen, and oxygen and M may include at least one of transition metal, rare earth metal, noble metal, aluminum, gallium, and indium. Alternatively, the buffer layer 162 may include a compound having chemical formula DₐM_{b}[GₓT_{y}]_{c} (where 0≦a/(a+b+c)≦0.2, 0≦b(a+b+c)≦0.1, and 0.3≦x(x+y)≦0.7). In the chemical formula, D may include at least one of carbon, nitrogen, and oxygen, M may include at least one of transition metal, aluminum, gallium, and indium, G may include germanium, and T may include tellurium. In the chemical formula, Gₓ may be Geₓ₁G′ₓ₂ (0.8≦x1(x1+x2)≦1). G′ may be Group 3A element or Group 5A element. For example, G′ may be aluminum, gallium, indium, silicon, tin, arsenic, antimony, or bismuth. In the chemical formula, T_{y} may be Te_{y1}Se_{y2} (where 0.8≦y1(y1+y2)≦1). The buffer layer 162 may relatively contain more germanium or tellurium than Ge—Sb—Te, which is a general phase-change material.

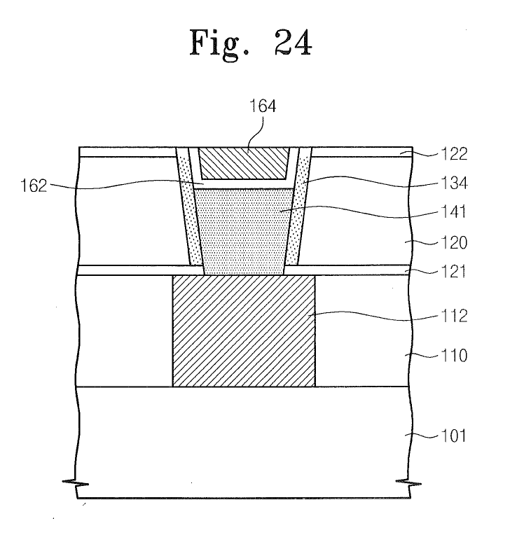

Referring to FIGS. 23 and 24, an upper electrode layer 164 is formed on the phase-change material layer 141 to cover the surface of the mold insulating layer 120, while filling the opening 126. A planarization process may be performed to the upper electrode layer 164. The planarization process may be chemical mechanical polishing process. The second etching stop layer 122 may function as an etching stop layer in the planarization process. The upper surfaces of the spacer 134, the upper electrode 164, and the second etching stop layer 122 may have the flat coplanar surface, as shown in FIG. 24, by the planarization process. Therefore, the upper electrode 164 may have a cross-section of a tetragonal shape (such as an isosceles trapezoid shape) and may extend in the second direction in the opening 126. The upper electrode 164 may have a line shape intersecting the word line. The upper electrode 164 with the line shape may be utilized as the bit line BL (see FIG. 25).

The upper electrode 164 may include, for example, titanium nitride, titanium aluminum nitride, tantalum nitride, molybdenum nitride, niobium nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, titanium oxynitride, titanium aluminum oxynitride, tungsten oxynitride, tantalum oxynitride, titanium, tungsten, molybdenum, tantalum, titanium silicide, tantalum silicide, graphite, or a combination thereof.

Accordingly, the phase-change material layer 141 and the upper electrode 164 completely may fill the opening 126 of the mold insulating layer 120, and thus may have a form confined in the opening 126. The upper surfaces of the mold insulating layer 120 (or the second etching stop layer 122), the spacer 134, and the upper electrode 164 may have a flat coplanar surface.

Referring to FIG. 25, a second inter-layer insulating layer 170 may be formed on the mold insulating layer 120. The second inter-layer insulating layer 170 may cover the upper electrode 164.

A contact plug 172 may be formed in the though-holes of the second inter-layer insulating layer 170 and the second etching stop layer 122 to come into contact with the upper electrode 164. A bit line BL may be formed on the second inter-layer insulating layer 170 to come into contact with the contact plug 172. The bit line BL may be electrically connected to the upper electrode 164 via the contact plug 172 of the second inter-layer insulating layer 170.

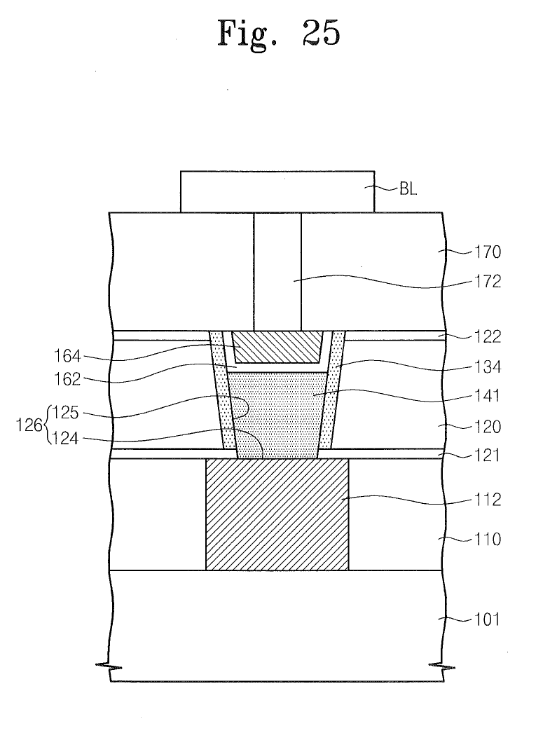

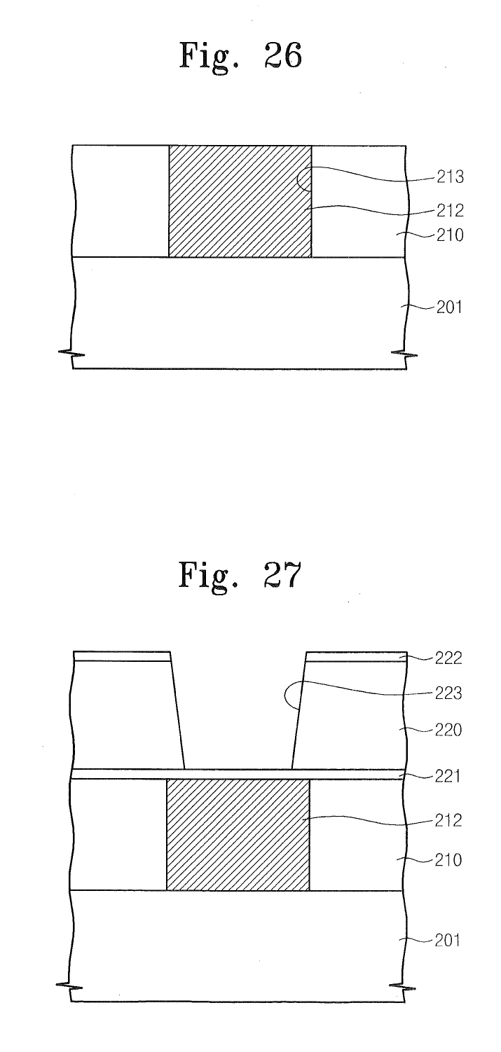

FIGS. 26 to 34 are cross-sections taken along the line I-I′ of FIG. 4 illustrating processing steps in the fabrication of phase changeable memory device according to some embodiments of the inventive concept. The similar reference numerals are given to substantially the same elements as those of embodiments of the inventive concept discussed above with respect to FIGS. 16 through 25 and, therefore, the detailed description of these features will not be repeated in the interest of brevity.

Referring to FIG. 26, a semiconductor substrate 201 is prepared. A first inter-layer insulating layer 210 is formed on the semiconductor substrate 201. A though hole 213 may be formed in the first inter-layer insulating layer 210. The through hole 213 may be filled with a conductive material. A planarization process may be performed to the conductive material to form the lower electrodes 212 in the first inter-layer insulating layer 210. The lower electrodes 212 may be exposed on the upper surface of the first inter-layer insulating layer 210. The lower electrodes 212 including the conductive material may be utilized as the heating electrodes of the phase changeable memory device.

Referring to FIG. 27, a mold insulating layer 220 is formed on the first inter-layer insulating layer 210 and the lower electrodes 212. Before the mold insulating layer 220 is formed, a first etching stop layer 221 may be formed. A second etching stop layer 222 may further be formed on the mold insulating layer 220. A preliminary opening 223 may be formed in the second etching stop layer 222 and the mold insulating layer 220 to expose the first etching stop layer 221. The preliminary opening 223 may overlap with the lower electrodes 212.

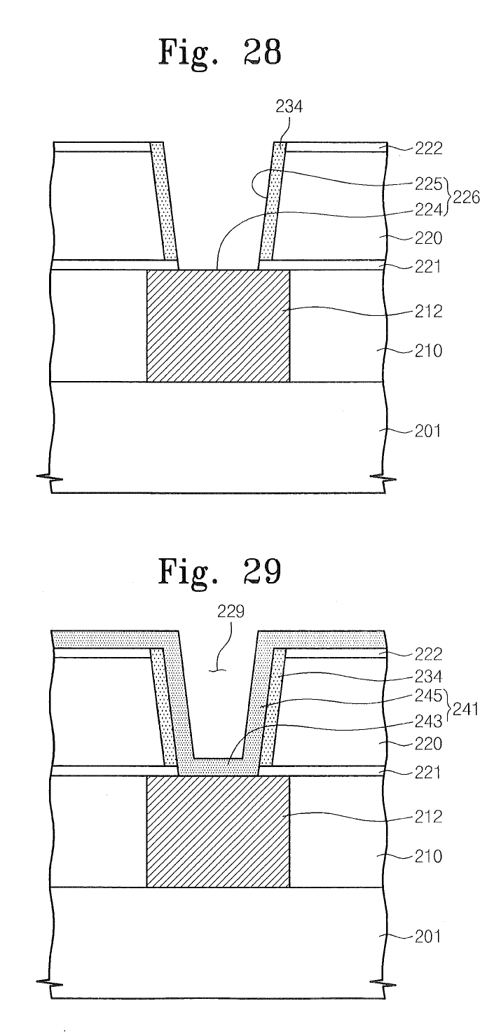

Referring to FIG. 28, a spacer 234 may be formed on the sidewall of the preliminary opening 223. The forming of the spacer 234 may include forming a spacer material layer covering the sidewall of the preliminary opening 223 and the upper surface of the second etching stop layer 222. The spacer 234 may be formed on the sidewall of the preliminary opening 226 by performing an anisotropic etching process to the spacer material layer. The opening 226 may be formed to expose the lower electrode 212 by etching the first etching stop layer 221 using the spacer 234 as an etching mask.

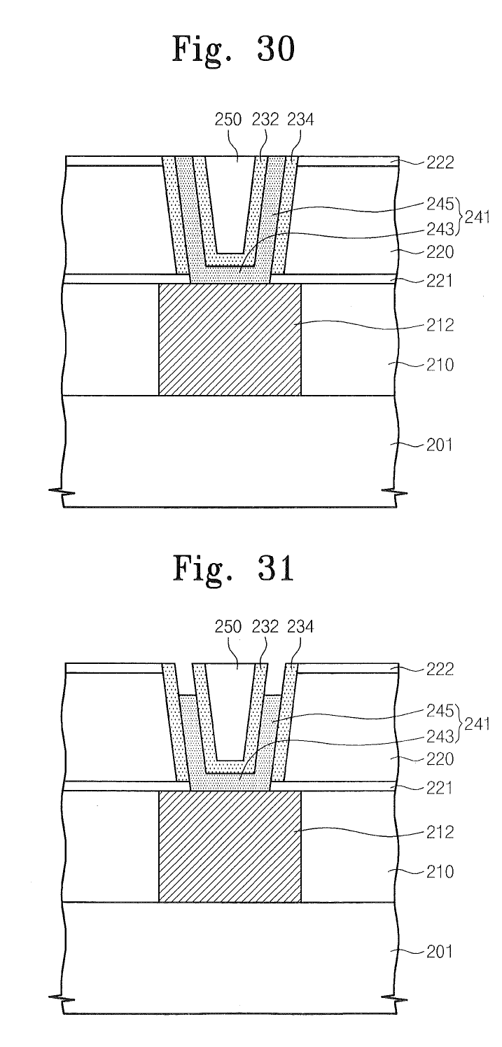

Referring to FIGS. 29 through 31, a phase-change material film may be formed along the profile of the mold insulating layer 220 including the opening 226. A gap-fill insulating layer 250 may be formed on the region, where the phase-change material film 241 is formed, to fill the opening 226. Before the gap-fill insulating layer 250 is formed, a protective layer 232 may be formed. A planarization process may be performed to the gap-fill insulating layer 250 and the phase-change material film to form the phase-change material layer 241. The planarization process may be chemical mechanical polishing process. The second etching stop layer 222 may function as an etching stop layer in the planarization process. The upper surfaces of the gap-fill insulating layer 250, the protective layer 232, the spacer 234, and the phase-change material layer 241 may have the flat coplanar surface, as in shown FIG. 30, by the planarization process. Therefore, the phase-change material layer 241 may have a U-shaped cross-section and may extend in the second direction in the opening 226. After the planarization process, the upper surface of the phase-change material layer 241 may be lowered below the surface of the mold insulating layer 220 by performing a selective etching process. The selective etching process may be reactive ion etching of using RF power.

The phase-change material layer 241 may include a chalcogenide material, as in the above-described embodiments of the inventive concept. The protective layer 232 may prevent the material from diffusing between the phase-change material layer 241 and the gap-fill insulating layer 250. The protective layer 232 may partially fill an inner space 229 of the phase-change material layer 241. The protective layer 232 may include, for example, silicon oxide, silicon nitride, silicon oxynitride, titanium carbon nitride, titanium oxide, zirconium oxide, magnesium oxide, hafnium oxide, or aluminum oxide. The gap-fill insulating layer 250 may completely fill the inner space 229. The gap-fill insulating layer 250 may include a silicon oxide layer with a god gap-fill characteristic, such as high density plasma silicon oxide, PE-TEOS, BPSG, USG, FOX, HSQ or SOG. The gap-fill insulating layer 250 may be a silicon nitride layer or a silicon oxynitride layer.

The phase-change material layer 241 may include a bottom portion 243, which comes into contact with lower electrodes 212, and a sidewall portion 245, which extends upwardly from both ends of the bottom 243. The sidewall portion 245 has the upper surface below the surface of a mold insulating layer 220. The bottom portion 243 may be provided the bottom surface 224 (see FIG. 28) of the opening 226 and the sidewall portion 245 may be provided in the side surface 225 (see FIG. 28) of the opening 226. The bottom portion 243 may come into contact with the lower electrodes 212, and the sidewall portion 245 may extend from the bottom portion 243 to an upper electrode 264. Therefore, the phase-change material layer 241 may have the U-shaped cross-section. The regions, where the phase-change material layer 241 and the lower electrodes 212 come into contact with each other, may be the phase changeable regions where a phase change occurs in accordance with the Joule's heat by the current supplied via the lower electrodes 212 serving as the heating electrodes.

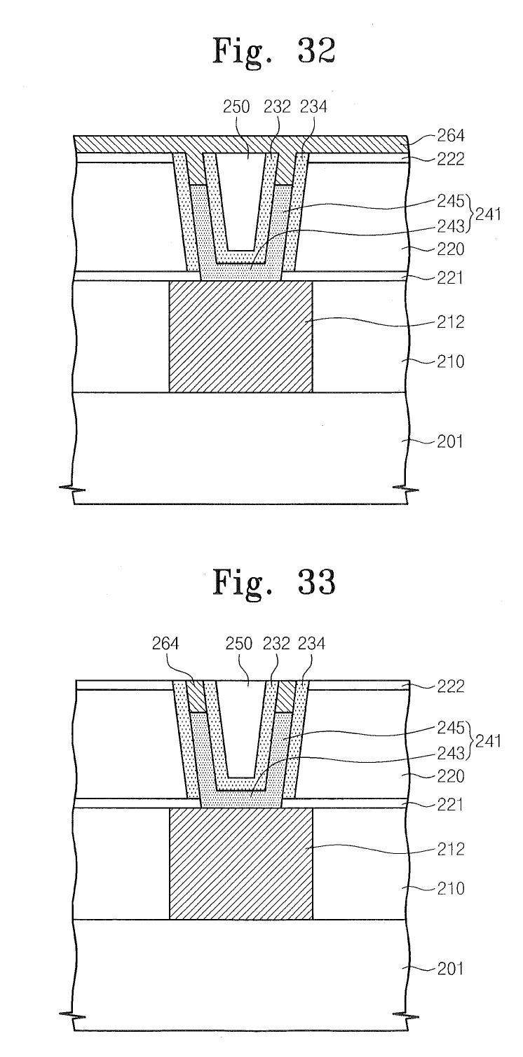

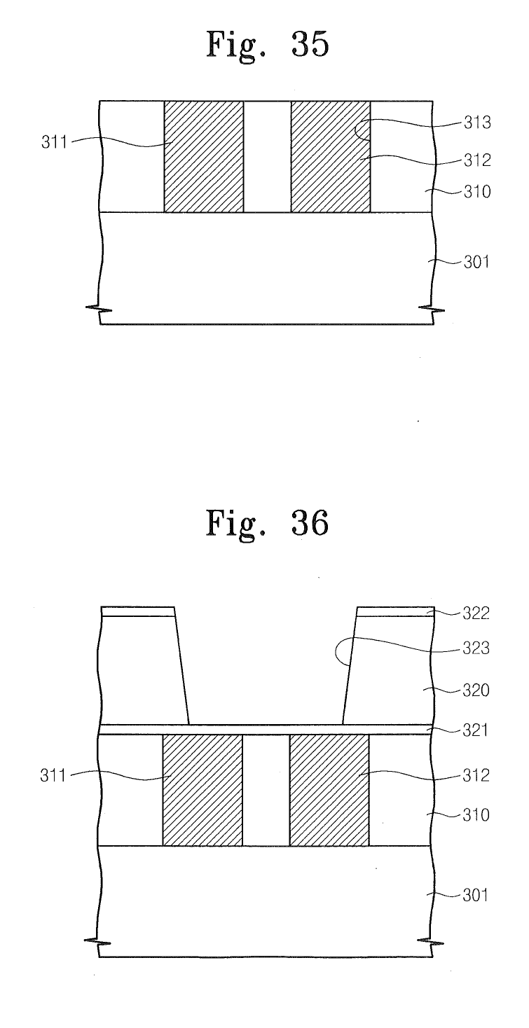

Referring to FIGS. 32 and 33, the upper electrode 264 is formed to cover upper surfaces of the sidewall portions 245 of the phase-change material layer 241 and a surface of the mold insulating layer 220. A planarization process may be performed to the upper electrode 264. The planarization process may be chemical mechanical polishing process. The second etching stop layer 222 may function as an etching stop layer in the planarization process. The upper surfaces of the second etching stop layer 222, the spacer 234, and the upper electrode 264 may have the flat coplanar surface, as in shown FIG. 33, by the planarization process. Therefore, the upper electrode 264 may be locally formed on the upper surfaces of the sidewall portions 245 of the phase-change material layer 241 and may extend in the second direction in the opening 226. The upper electrode 264 may have the line shape intersecting the word line. The upper electrode 264 with the line shape may be utilized as the bit line BL (see FIG. 35).

Therefore, the phase-change material layer 241 and the upper electrode 264 may have a form confined in the opening 226 of the mold insulating layer 220 by the gap-fill insulating layer 250. The upper surfaces of the gap-fill insulating layer 250, the protective layer 232, the upper electrode 264, the spacer 234, and the mold insulating layer 220 (or the second etching stop layer 222) may have the flat coplanar surface.

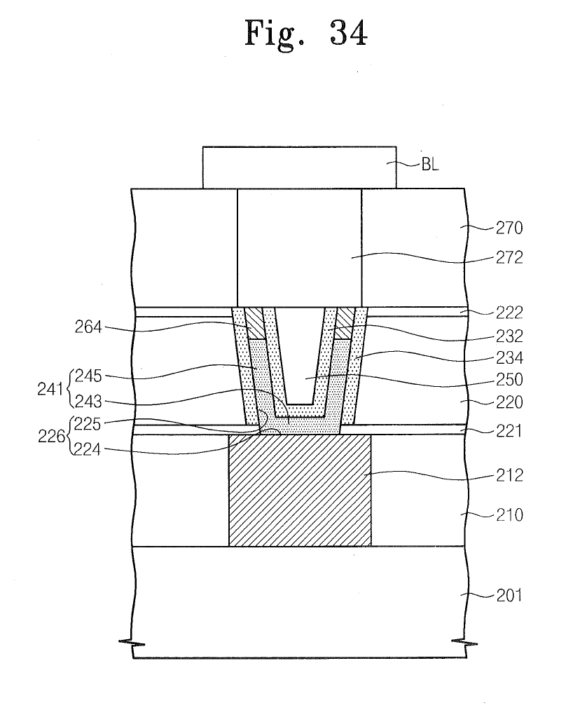

Referring to FIG. 34, a second inter-layer insulating layer 270 may be formed on the mold insulating layer 220. The second inter-layer insulating layer 270 may cover the upper electrode 264. A contact plug 272 may be formed in the through hole of the second inter-layer insulating layer 270 to come into contact with the upper electrode 264. A bit line BL may be formed on the second inter-layer insulating layer 270 to come into contact with the contact plug 272. The bit line BL may be electrically connected to the upper electrode 264 via the contact plug 272 of the second inter-layer insulating layer 270.

FIGS. 35 through 40 are cross-sections taken along the line I-I of FIG. 6 illustrating processing steps in the fabrication of phase changeable memory devices in accordance with some embodiments of the inventive concept. The similar reference numerals are given to substantially the same elements as those of embodiments of the inventive concept discussed above with respect to FIGS. 26 through 35 and, therefore, detailed description of these features will not be repeated in the interest of brevity.

Referring to FIG. 35, a semiconductor substrate 301 is prepared. A first inter-layer insulating layer 310 is formed on the semiconductor substrate 301. A through hole 313 may be formed in the first inter-layer insulating layer 310. The through-hole 313 may be filled with a conductive material. A pair of lower electrodes 311 and 312 distant from each other in the first inter-layer insulating layer 310, may be formed by performing a planarization process to the conductive material. The lower electrodes 311 and 312 may be exposed on the upper surface of the first inter-layer insulating layer 310. The lower electrodes 311 and 312 including the conductive material may be utilized as the heating electrodes of the phase changeable memory device.

The lower electrodes 311 and 312 may be electrically connected to the selective element. One pair of lower electrodes 311 and 312 may be distant from each other in the first direction on the word line. One pair of lower electrodes 311 and 312 may include the first lower electrode 311 and the second lower electrode 312.

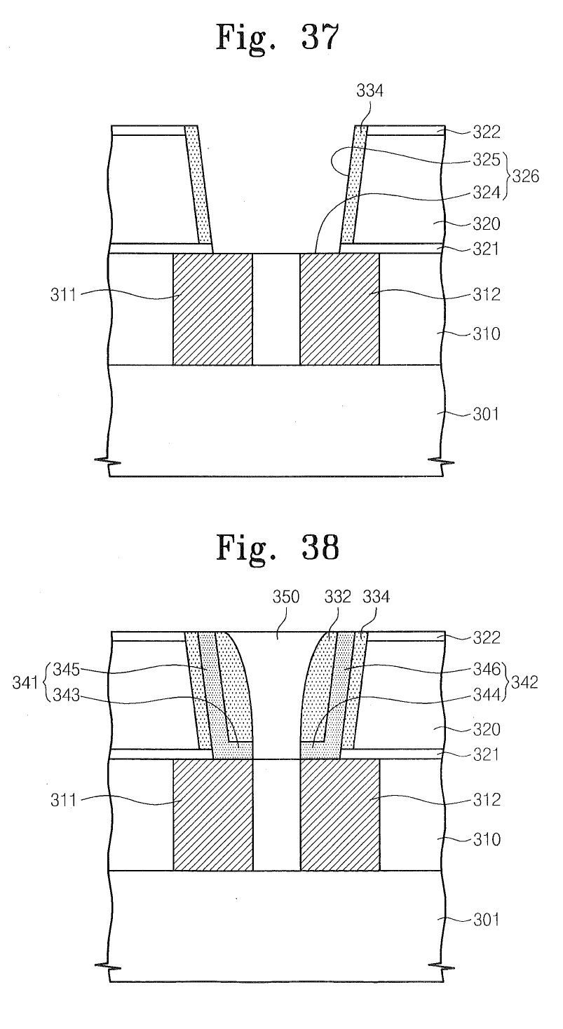

Referring to FIGS. 36 and 37, the mold insulating layer 320 is formed on the fist inter-layer insulating layer 310 and the lower electrodes 311 and 312. Before the mold insulating layer 320 is formed, a first etching stop layer 321 may be formed. A second etching stop layer 322 may further be formed on the mold insulating layer 320. A preliminary opening 323 may be formed in the second etching stop layer 322 and the mold insulating layer 320 to expose the first etching stop layer 321. The preliminary opening 323 may overlap with the lower electrodes 311 and 312.

A spacer 334 may be formed on the sidewall of the preliminary opening 323. The forming of the spacer 334 may include forming a spacer material layer to cover the sidewall of the preliminary opening 323 and the upper surface of the second etching stop layer 322. The spacer 334 may be formed on the sidewall of the preliminary opening 323 by performing an anisotropic etching process to the spacer material layer. The opening 326 may be formed to expose both of the lower electrodes 311 and 312 by etching the first etching stop layer 321 using the spacer 334 as an etching mask.

Referring to FIG. 38, a phase-change material film ma be formed along the profile of the mold insulating layer 320 including the opening 326. A protective layer may be conformally formed on the phase-change material film. The thickness of the protective layer may be smaller than the half of the width of the bottom surface 324 of the opening 326. One pair of protective layer spacers 332 distant from each other may be formed on the phase-change material film in the vicinity of the sidewall of the opening 326 by performing an anisotropic etching process, such as etch back process, to the protective layer. One pair of protective layer spacers 332 may expose a portion of the phase-change material film on the bottom surface 324 of the opening 326.

The phase-change material film may include a phase-change material such as a chalcogenide material, as in the above-described embodiments of the inventive concept. The protective layer may include the materials mentioned in the some embodiments of the inventive concept.

One pair of phase-change material layers 341 and 342 distant from each other may be formed by etching the phase-change material film using one pair of protective layer spacers 332 as etching masks. The etching process may include an anisotropic etching process. The protective layer spacers 322 may protect one pair of phase-change material layers 341 and 342 from damage in the anisotropic etching.

One pair of phase-change material layers 341 and 342 may include a first phase-change material layer 341 and a second phase-change material layer 342. The first phase-change material layer 341 may include a first bottom portion 343 coming into contact with the first lower electrode 311 and a first sidewall portion 345 extending upwardly from one end of the first bottom portion 343. The first bottom portion 343 and the first sidewall portion 345 may form an L-shaped cross-section. The second phase-change material layer 342 may include a second bottom portion 344 coming into contact with the second lower electrode 312 and a second sidewall portion 346 extending from one end of the second bottom portion 344 to the upper electrode 364. The second bottom portion 344 and the second sidewall portion 346 may form an L-shaped cross-section. The bottom portions 343 and 344 may be provided on the bottom surface 324 of the opening 326, and the sidewall portions 345 and 346 may be provided on the side surfaces 325 of the opening 326. The first phase-change material layer 341 and the second phase-change material layer 342 may have an L-shaped cross-section.

The protective layer spacers 332 may cover the upper surfaces of the bottom portions 343 and 344 of the phase-change material layers 341 and 342 and the inner surfaces of the sidewall portions 345 and 346 of the phase-change material layers 341 and 342. The protective layer spacers 332 may expose the upper surfaces of the sidewall portions 345 and 346. The protective layer spacers 332 may have a spacer shape covering the upper surfaces of the bottom portions 343 and 344 of the phase-change material layers 341 and 342 and the inner surfaces of the sidewall portions 345 and 346 of the phase-change material layers 341 and 342. A lower portion of the protective spacers 332 may be aligned with the other ends of the bottom portions 343 and 344. The upper portions of the protective spacers 332 may have a coplanar surface with the upper surfaces of the preliminary phase-change material layers 341 and 342. The protective spacers 332 may prevent the material from diffusing between the phase-change material layers 341 and 342 and the gap-fill insulating layer 350.

The gap-fill insulating layer 350 may be formed between the protective spacers 332 to completely fill the remaining space of the opening 326. The gap-fill insulating layer 350 may contain the materials mentioned in some embodiments of the inventive concept discussed above. The gap-fill insulating layer 350 may expose the upper surfaces of the phase-change material layers 341 and 342.

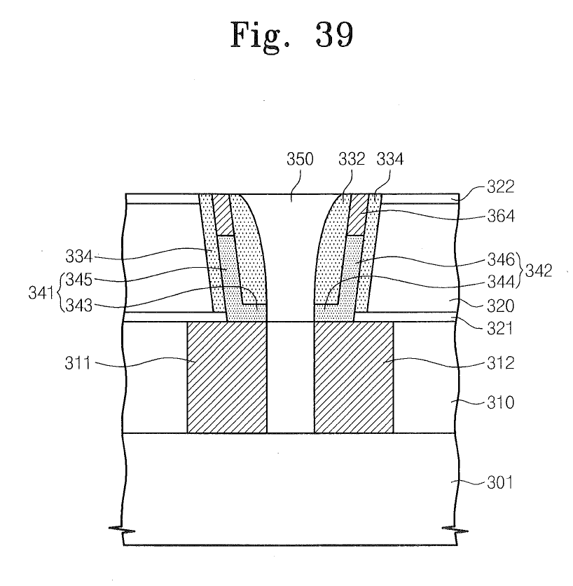

Referring to FIG. 39, the upper surfaces of the first phase-change material layer 341 and the second phase-change material layer 342 may be lowered below the surface of the mold insulating layer 320 by performing a selective etching process. The selective etching process may be reactive ion etching of using RF power. Accordingly, the first sidewall portion 345 and the second sidewall portion 346 may have an upper surface below the surface of the mold insulating layer 320. The first phase-change material layer 341 and the second phase-change material layer 342 may be disposed to face to each other in a mirror form. The term “facing” may mean that the other end of the first bottom portion 343 and the other end of the second bottom portion 344 are adjacent to each other. The regions, where the phase-change material layers 341 and 342 and the lower electrodes 311 and 312 come into contact with each other, may be phase changeable regions where a phase change occurs in accordance with the Joule's heat by the current supplied via the lower electrodes 311 and 312 serving as heating electrodes.

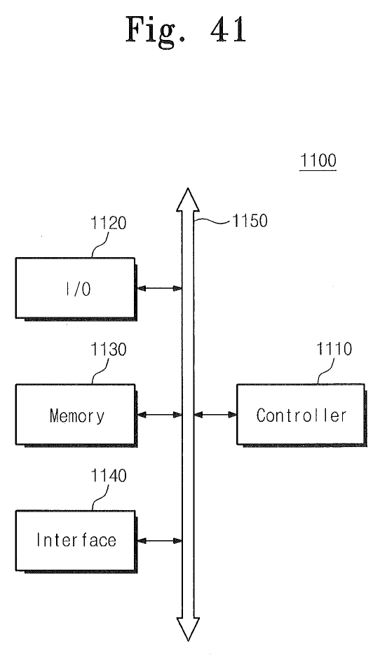

The upper electrode 364 may be locally formed on the upper surfaces of the sidewall portions 345 and 346 of the first phase-change material layer 341 and the second phase-change material layer 342. The upper surfaces of the gap-fill insulating layer 350, the protective layer spacer 332, the spacer 334, the second etching stop layer 322, and the upper electrode 364 may have a flat coplanar surface. The upper electrode 364 may extend in the second direction in the opening 326. The upper electrode 364 may have a line shape intersecting the word line. The upper electrode 364 with the line shape may be utilized as a bit line BL (see FIG. 41).

Accordingly, by the protective spacer 322 and the gap-fill insulating layer 350, the phase-change material layers 341 and 342 and the upper electrode 364 may have the form confined in the opening 326 of the mold insulating layer 320. Upper surfaces of the gap-fill insulating layer 350, the protective layer spacer 322, the protective layer spacer 332, the upper electrode 364, the spacer 334, and the mold insulating layer 320 (or the second etching stop layer 322) may have the flat coplanar surface.

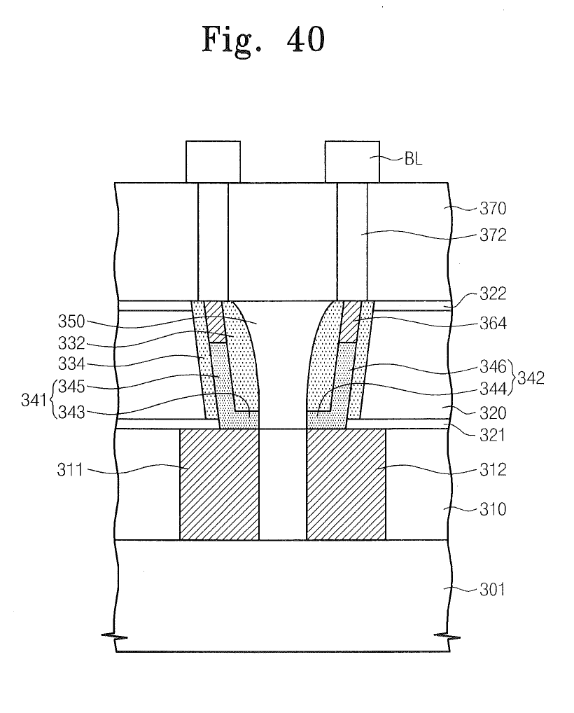

Referring to FIG. 40, a second inter-layer insulating layer 370 may be formed on the mold insulating layer 320. The second inter-layer insulating layer 370 may cover the upper electrode 364. Contact plugs 372 may be formed in the through holes of the second inter-layer insulating layer 370 to come into contact with one pair of upper electrodes 364, respectively. Bit lines BL may be formed on the second inter-layer insulating layer 370 to come into contact with the contact plugs 372. The bit lines BL may be electrically connected to one pair of upper electrodes 364 via the contact plugs 372 of the second inter-layer insulating layer 370, respectively.

FIG. 41 is a schematic block diagram illustrating an example of memory system including the phase changeable memory device according to some embodiments of the inventive concept. As illustrated in FIG. 41, a memory system 1100 is applicable to a personal digital assistant (PDA), a portable computer, a web tablet, a wireless phone, a mobile phone, a digital music player, a memory card, and any device capable of transmitting and/or receiving information in a wireless environment.

The memory system 1100 may include a controller 1110, an input/output (I/O) device 1120 such as a key pad, a key board, or a display device, a memory 1130, an interface 1140, and a bus 1150. The memory 1130 and the interface 1140 may communicate with each other via the bus 1150

The controller 1110 may include at least one of a microprocessor, a digital signal processor, a microcontroller, and other processors similar thereto. The memory 1130 may store commands executed by the controller 1110. The I/O device 1120 may receive an input of data or a signal from the outside of the memory system 1100 or output data or a signal to the outside of the memory system 1100. For example, the I/O device 1120 may include a key pad, a key board, or a display device.

The memory 1130 includes the phase changeable memory device according to some embodiments of the inventive concept. The memory 1130 may further include other kinds of memories, a volatile memory capable of making random access at any time, and other various kinds of memories.

The interface 1140 functions as transmitting data to a communication network or receiving data from a communication network.

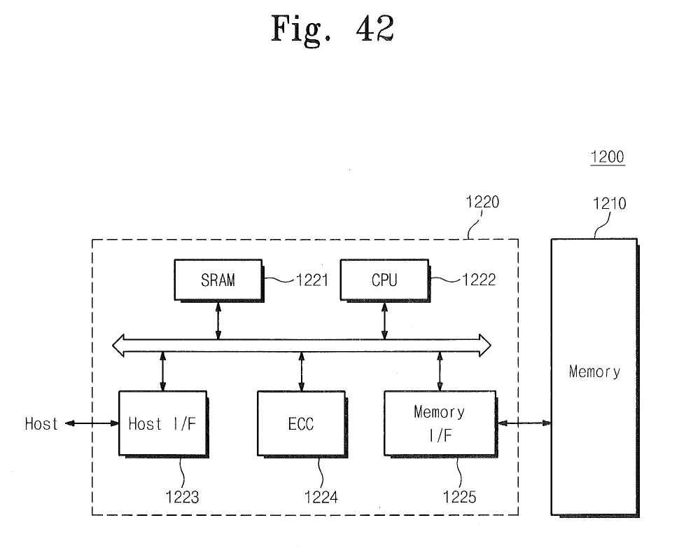

FIG. 42 is a schematic block diagram illustrating an example of a memory card including the phase changeable memory device according to some embodiments of the inventive concept. As illustrated in FIG. 42, for supporting a large data storage capability, a memory card 1200 is mounted with a memory device 1210 including the phase changeable memory device according to the inventive concept. The memory card 1200 according to some embodiments of the inventive concept includes a memory controller 1220 controlling general data exchange between a host and the memory device 1210.

A Static Random Access Memory (SRAM) 1221 is used as a work memory of a central processing unit (CPU) 1222. A host interface (I/F) 1223 has a data exchange protocol of the host connected to the memory card 1200. An error correction coding (ECC) block 1224 detects and corrects errors contained in data read from the memory device 1210 with a multi-bit characteristic. A memory interface (I/F) 1225 interfaces with the memory device 1210 including the phase changeable memory device according to some embodiments of the inventive concept. The central processing unit 1222 executes general control operations to exchange data of the memory controller 1220. Although not illustrated in the drawing, it is apparent to those skilled in the art that the memory card 1200 according to some embodiments of the inventive concept may further include a ROM (Read Only Memory, which is not illustrated) storing code data for interfacing with the host.

The phase changeable memory device, the memory card, or the memory system according to some embodiments of the inventive concept, a highly integrated memory system may be provided. In particular, the phase changeable memory device may be provided to a solid state drive (SSD) recently studied. In this case, it is possible to realize a highly integrated memory system.

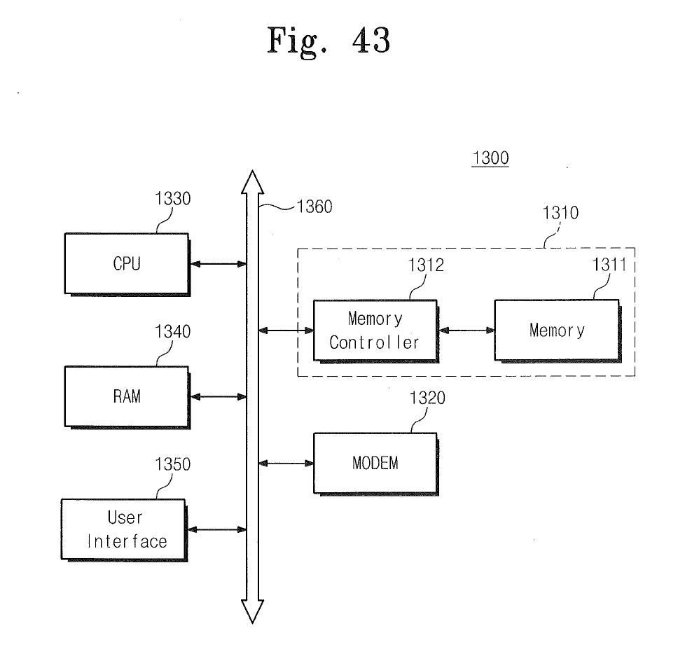

Referring now to FIG. 43, a schematic block diagram illustrating an example of an information processing system on which a non-volatile memory device according to some embodiments of the inventive concept will be discussed. As illustrated in FIG. 43, a memory system 1310, which includes the phase changeable memory device 1311 according to some embodiments of the inventive concept and a memory controller 1312 controlling general data exchange between a system bus 1360 and the phase changeable memory device 1311, is mounted in an information processing system such as a mobile device or a desktop computer. An information processing system 1300 according to some embodiments of the inventive concept includes the memory system 1310, a MODEM (Modulator and DEModulator) 1320, a central processing unit 1330, a RAM 1340, and a user interface 1350 electrically connected to the flash memory system 1310 via a system bus 1360. The memory system 1310 may have substantially the same configuration as that of the memory system mentioned above. The memory system 1310 stores data processed by the central processing unit 1330 or data input from the outside. Here, the above-described memory system 1310 may be formed as a solid state drive. In this case, the information processing system 1300 may stably stores large data in the flash memory system 1310. Since a resource necessary for error correction in the flash memory system 1310 may be reduced with an increase in reliability, a high-speed data exchanging function may be realized in the information processing system 1300. Although not illustrated, it is apparent to those skilled in the art that an application chipset, a camera image processor (CIS), an input/output device, or the like may further be included in the information processing system 1300 according to some embodiments of the inventive concept.

The memory device or the memory system according to some embodiments of the inventive concept may be realized in various types of packages. For example, the memory device or the memory system according to some embodiments of the inventive concept may be packaged in a way such as package on package (PoP), ball grid array (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), or wafer-level processed stack package (WSP).

According to some embodiments of the inventive concept, the phase-change material layer and the upper electrode may have the form confined in the opening of the mold insulating layer. Due to such a configuration, since photolithography and etching are omitted upon forming the upper electrode, the phase-change material layer can not be damaged. Accordingly, it is possible to improve reliability of the phase changeable memory device. Moreover, a misalign problem may be solved between the phase-change material layer and the upper electrode.

According to some embodiments of the inventive concept, the spacer may be interposed between the mold insulating layer and the phase-change material layer and the upper electrode. Accordingly, since it is possible to adjust the contact length (or the area) between the lower electrode and the phase-change material layer, a high integrated phase changeable memory device can be realized.

Although the present inventive concept has been described in connection with some embodiments of the inventive concept illustrated in the accompanying drawings, it should be understood to those skilled in the art embody that the present inventive concept may be realizes as other specific embodiments without departing from the scope and spirit of the invention. Therefore, the above-described embodiments are to be considered illustrative and not restrictive.

1. A phase changeable memory device comprising:
a mold insulating layer on a substrate, the mold insulating layer defining an opening therein;
a phase-change material layer in the opening, the phase-change material comprising a an upper surface that is below a surface of the mold insulating layer;
a first electrode in the opening and on the phase-change material layer; and
a spacer between a sidewall of the mold insulating layer and the phase-change material layer and the first electrode, wherein an upper surface of the first electrode is coplanar with the surface of the mold insulating layer.

2. The phase changeable memory device of claim 1, wherein the substrate further comprises a second electrode electrically connected to a lower surface of the phase-change material layer.

3. The phase changeable memory device of claim 1, wherein the opening is completely filled with the phase-change material layer and the first electrode.

4. The phase changeable memory device of claim 1, wherein the phase-change material layer comprises:
a bottom portion that contacts the second electrode; and
a sidewall portion extending from the bottom portion to the first electrode.

5. The phase changeable memory device of claim 4, wherein the phase-change material layer has a U-shaped cross-section including the bottom portion and the sidewall portion.

6. The phase changeable memory device of claim 5, wherein the first electrode is locally formed on an upper surface of the sidewall portion of the phase-change material layer.

7. The phase changeable memory device of claim 6, further comprising a gap-fill insulating layer filling an inner space formed by the phase-change material layer and the first electrode.

8. The phase changeable memory device of claim 7, further comprising a protective layer between the gap-fill insulating layer, and the phase-change material layer and the first electrode.

9. The phase changeable memory device of claim 4, wherein the phase-change material layer has an L-shaped cross-section including the bottom portion and the sidewall portion.

10.-20. (canceled)
